(19) United States
(12) Patent Application Publication
(10) Pub. No.: US 2025/0112124 A1
(43) Pub. Date: Apr. 3, 2025

(54) DEEP CAVITY ARRANGEMENTS ON INTEGRATED CIRCUIT PACKAGING

(71) Applicant: Intel Corporation, Santa Clara, CA (US)

(72) Inventors: Jeremy Ecton, Gilbert, AZ (US); Aleksandar Aleksov, Chandler, AZ (US); Leonel Arana, Phoenix, AZ (US); Gang Duan, Chandler, AZ (US); Benjamin Duong, Phoenix, AZ (US); Hongxia Feng, Chandler, AZ (US); Tarek Ibrahim, Mesa, AZ (US); Brandon C. Marin, Gilbert, AZ (US); Tchefor Ndukum, Chandler, AZ (US); Bai Nie, Chandler, AZ (US); Srinivas Pietambaram, Chandler, AZ (US); Bohan Shan, Chandler, AZ (US); Matthew Tingey, Mesa, AZ (US)

(73) Assignee: Intel Corporation, Santa Clara, CA (US)

(21) Appl. No.: 18/374,555

(22) Filed: Sep. 28, 2023

(51) Int. Cl. H01L 23/482; H01L 23/00; H01L 23/31; H01L 23/498; H01L 25/065

(52) U.S. Cl. CPC H01L 23/4821; H01L 23/315; H01L 23/49822; H01L 24/16; H01L 24/97; H01L 25/0657; H01L 2224/16227; H01L 2224/16235; H01L 2224/97; H01L 2225/06517; H01L 2924/01029; H01L 2924/068; H01L 2924/1431; H01L 2924/1435

(57) ABSTRACT

DEEP CAVITY ARRANGEMENTS ON INTEGRATED CIRCUIT PACKAGING An electronic package, comprises a substrate core; dielectric material of one or more dielectric material layers over the substrate core, and having a plurality of metallization layers comprising an upper-most metallization layer; and an integrated circuit (IC) die embedded within the dielectric material and below the upper-most metallization layer. The package also has a metallization pattern within the dielectric material and below the IC die; and a gap within the dielectric material and extending around the metallization pattern.

### BACKGROUND

Bridge dice such as Embedded multi-die interconnect bridges (EMIBs) and EMIBs with through silicon vias (EMIB-Ts) couple one integrated circuit (IC) die to another IC die. Some bridge dice are placed in deep cavities on integrated circuit (IC) packages in order to embed the bridge die within dielectric layers of the packaging. Some bridge dice have a metallization pattern such as conductive redistribution layers (RDLs) located at the bottom of the cavity and a bridge die is placed over the metallization pattern for coupling thereto. The deep cavity is often formed by laser drilling that can form inter-metallic compounds (IMCs) at the metallization pattern with solder or other conductive layers, which in turn reduces the quality of electrical connections between the bridge die and the metallization pattern. The laser also can damage these layers directly. The deep cavity also typically has tapered sidewalls as a result of the use of the laser to drill the deep cavity, resulting in a wastefully wide footprint for the deep cavity on the IC package which cannot be used to hold metallization.

### BRIEF DESCRIPTION OF THE DRAWINGS

The material described herein is illustrated by way of example and not by way of limitation in the accompanying figures. For simplicity and clarity of illustration, elements illustrated in the figures are not necessarily drawn to scale. For example, the dimensions of some elements may be exaggerated relative to other elements for clarity. Further, where considered appropriate, reference labels have been repeated among the figures to indicate corresponding or analogous elements. In the figures:

FIG. 1A is a cross-sectional schematic diagram of an example integrated circuit (IC) package with one or more dep cavity IC dice according to at least one of the implementations disclosed herein;

FIG. 1B is a close-up cross-sectional schematic diagram of the example IC package of FIG. 1A according to at least one of the implementations disclosed herein;

FIG. 2 is a simplified top view, see-trough cross-section of an area near an EMIB of the IC package of FIG. 1 according to at least one of the implementations disclosed herein;

FIG. 3A is a method of manufacturing an IC package according to at least one of the implementations disclosed herein;

FIG. 3B is a schematic diagram of a close-up cross-sectional view of an intermediate assembly stage of the method of FIG. 3A according to at least one of the implementations disclosed herein;

FIGS. 4-10 are IC package manufacturing stages of the IC package of FIG. 1 according to at least one of the implementations disclosed herein;

FIG. 11 is a cross-sectional schematic diagram of another integrated circuit (IC) package with one or more deep cavity IC dice according to at least one of the implementations disclosed herein;

FIG. 12 is a cross-sectional schematic diagram of an alternative dielectric deep cavity of an IC package during an intermediate assembly stage of the IC package according to at least one of the implementations disclosed herein;

FIGS. 13-19 are cross-sectional schematic diagrams of example IC package manufacturing stages of the IC package of FIG. 11 according to at least one of the implementations disclosed herein;

FIGS. 20-21 are cross-sectional schematic diagrams of example alternative IC package manufacturing stages for the IC package of FIG. 11 according to at least one of the implementations disclosed herein;

FIG. 22 is a cross-sectional schematic diagram of yet another example integrated circuit (IC) package with one or more deep cavity IC dice according to at least one of the implementations disclosed herein;

FIGS. 23-27 are cross-sectional schematic diagrams of example IC package manufacturing stages of the IC package of FIG. 22 according to at least one of the implementations disclosed herein;

FIG. 28 is a functional block diagram of an electronic computing device including an IC package with deep cavity IC die in accordance with various implementations herein; and

FIG. 29 is a schematic diagram of a mobile computing platform and a data server machine employing an IC package with a deep cavity IC die in accordance with various implementations.

### DETAILED DESCRIPTION

Implementations discussed herein variously describe electronic packages with deep cavity arrangements that significantly reduce intermetallic compound (IMC) growth at embedded bridge die or dice such as embedded multi-die interconnect bridges (EMIBs), EMIBs with through silicon vias (EMIB-Ts), chiplets, and other fine-pitch IC bridge structures although other implementations herein also may be used with non-bridge embedded die arrangements. Otherwise, structures such as deep trench capacitor dies may be embedded in the cavity instead. Deep cavity arrangements additionally or alternatively may significantly reduce the size of the unusable footprint above the deep cavity to permit more metallization near the cavity. These deep cavity arrangements are in accordance with various implementations.

The technologies described herein may be implemented in one or more electronic devices. Non-limiting examples of electronic devices that may utilize the technologies described herein include any kind of mobile device and/or stationary device, such as cameras, cell phones, computer terminals, desktop computers, electronic readers, facsimile machines, kiosks, laptop computers, netbook computers, notebook computers, internet devices, payment terminals, personal digital assistants, media players and/or recorders, servers (e.g., blade server, rack mount server, combinations thereof, etc.), set-top boxes, smart phones, tablet personal computers, ultra-mobile personal computers, wired telephones, combinations thereof, and the like. More generally, the technologies described herein may be employed in any of a variety of electronic devices including integrated circuit architecture with integrated circuit packaging large cavity architecture as described herein.

Implementations are described with reference to the enclosed figures. While specific configurations and arrangements are depicted and discussed in detail, it should be understood that this is done for illustrative purposes only. Persons skilled in the relevant art will recognize that other configurations and arrangements are possible without departing from the spirit and scope of the description. It will be apparent to those skilled in the relevant art that techniques and/or arrangements described herein may be employed in a variety of other systems and applications other than what is described in detail herein.

It also should be noted that directions and references (e.g., up, down, top, bottom, etc.) may be used merely to facilitate the description of features in the drawings and relationship between the features. Therefore, the following detailed description is not to be taken in a limiting sense and the scope of claimed subject matter is defined solely by the appended claims and their equivalents.

In the following description, numerous details are set forth. However, it will be apparent to one skilled in the art, that implementations may be practiced without these specific details. In some instances, well-known methods and devices are shown in block diagram form, rather than in detail, to avoid obscuring the implementations.

Reference throughout this specification to “an implementation” or “one implementation” or “some implementations” means that a particular feature, structure, function, or characteristic described in connection with the implementation is included in at least one implementation. Thus, the appearances of the phrase “in an implementation” or “in one implementation” or “some implementations” in various places throughout this specification are not necessarily referring to the same implementation. Furthermore, the particular features, structures, functions, or characteristics may be combined in any suitable manner in one or more implementations. For example, a first implementation may be combined with a second implementation anywhere the particular features, structures, functions, or characteristics associated with each of the two implementations are not mutually exclusive.

As used in the description and the appended claims, the singular forms “a”, “an” and “the” are intended to include the plural forms as well, unless the context clearly indicates otherwise. It will also be understood that the term “and/or” as used herein refers to and encompasses any and all possible combinations of one or more of the associated listed items.

The terms “coupled” and “connected,” along with their derivatives, may be used herein to describe functional or structural relationships between components. It should be understood that these terms are not intended as synonyms for each other. Rather, in particular implementations, “connected” may be used to indicate that two or more elements are in direct physical, optical, and/or electrical contact with each other. “Coupled” may be used to indicate that two or more elements are in either direct or indirect (with other intervening elements between them) physical, optical, or electrical contact with each other, and/or that the two or more elements co-operate or interact with each other (e.g., as in a cause an effect relationship).

The terms “over,” “under,” “between,” and “on” as used herein refer to a relative position of one component or material with respect to other components or materials where such physical relationships are noteworthy. For example, in the context of materials, one material or structure disposed over or under another may be directly in contact or may have one or more intervening materials. Moreover, one material disposed between two materials may be directly in contact with the two materials or may have one or more intervening materials. In contrast, a first material or structure “on” a second material or structure is in direct contact with that second material/structure. Similar distinctions are to be made in the context of component assemblies where a first component may be “on” or “over” a second component.

As used throughout this description, and in the claims, a list of items joined by the term “at least one of” or “one or more of” can mean any combination of the listed terms. For example, the phrase “at least one of A, B or C” can mean A; B; C; A and B; A and C; B and C; or A, B and C.

Herein, the term “conductive feature” or “metal feature” may refer to any metal structure within a package that is part of the extra-chip circuitry, and is generally embedded within the dielectric material of the package. Structures include traces, caps, contacts, and pads that are within a metallization layer or plane (e.g., in-plane). Vias or pillars that form interconnects interconnecting in-plane conductive features within adjacent metallization levels are included as well. “Conductive features” may be substituted by “metal features” or just “features” at times within the disclosure.

Herein, the term “circuit” or “module” may refer to one or more passive and/or active components that are arranged to cooperate with one another to provide a desired function. The term “signal” may refer to at least one current signal, voltage signal, magnetic signal, or data/clock signal.

The terms “substantially,” “close,” “approximately,” “near,” and “about,” generally refer to being within +/−10% of a target value (unless specifically specified). Unless otherwise specified the use of the ordinal adjectives “first,” “second,” and “third,” etc., to describe a common object, merely indicate that different instances of like objects are being referred to, and are not intended to imply that the objects so described must be in a given sequence, either temporally, spatially, in ranking, or in any other manner.

Also, chemical compounds without stoichiometry labels are not necessarily limited to 1:1 quantities. Thus, for example, “FeCo”, “FeNi”, “SnCuIn”, “NiWP” does not imply or limit the compound to a particular stoichiometry of those elements.

Deep cavity arrangements on integrated circuit packaging is described herein.

Redistribution layers (RDLs) at the bottom of deep cavities for bridge die such as EMIBs that have conductive metallization to transmit electrical signals and/or electrical power through the bottom of the EMIB. In these arrangements, the EMIBs may have through silicon vias (TSVs) and may be referred to as EMIB-Ts to receive the signals and/or power, and/or to provide the signals and power to additional dice interconnected to each other through the EMIB-T. It should be noted that ‘EMIB’ is used in the general sense herein and includes EMIB-Ts, unless the context suggests otherwise.

The RDL may have copper while tin solder on the RDL is often used to connect the RDL to the metallization on the EMIB. During construction of the packaging, the solder (or solder caps) is often placed on the RDLs before being covered with dielectric layers that are subsequently laser drilled to form the deep cavity.

Heat from the laser drilling to form the deep cavity, however, often causes undesired inter-metallic compounds (IMCs). Specifically, the reaction of copper and solder when heat is applied leads to the fast formation of IMCs that are generally more brittle, resulting in reduced mechanical integrity, and are less conductive, and therefore reduces performance of the IC package.

In attempts to reduce IMCs in deep cavities, typically a diffusion barrier layer may be placed between the solder and the RDL. The barrier layer, often formed of nickel when using a tin solder, reduces fast reaction kinetics and reduces interdiffusion of the copper of the RDL and the tin solder caused by the soldering process itself. The barrier layer additionally or alternatively is placed over the solder, RDL, and dielectric near the RDL as well and as a protective layer or laser stop so the laser does not contact these elements. Heat levels from the laser reached during deep cavity drilling, however, often still melts the protective layer anyway resulting in damage to the RDL, solder, and/or dielectric at the bottom of the drilled cavity as well as the generation of IMCs. By another arrangement, the solder is not placed on the RDL until after the cavity is drilled and the protective nickel layer is placed directly on the RDL. In this case, the same result occurs where the protective layer is melted and often inadequate to reduce damage to the RDL by the laser.

As another difficulty with deep cavities, the combination of the height of the cavity (greater than 50 microns) and taper angles caused by the laser (such as 80-85 degrees) results in a wide cavity opening or footprint with a wide outer upper rim of the deep cavity. The volume or space within the upper rim and above the target bottom of the cavity cannot be used for metallization to keep clear of the laser drilling to form the cavity. This in turn results in relatively long, wasteful, horizontal distances along the horizontal component of the tapered sidewall of the cavity. This can be measured by determining the minimum available horizontal distance from bumps (or caps) on the RDL in the bottom of the cavity coupling to the EMIB, and a bump of an interconnect for coupling to another device outside of the cavity, such as the dice being coupled to each other through the EMIB. Usually, the outside bump or interconnect is located at or above the same vertical level of the upper outer rim of the deep cavity. By one form, the core-to-bridge distance is often greater than 15 microns and even 35 microns for a 200 micron deep cavity depending on the type of laser used. It would be much more efficient to reduce those distances to provide more volume of the package near the upper outer rim of the deep cavity and bridge die available for additional metallization such as interconnects and bumps to other devices outside of the cavity.

To resolve these issues, a method of manufacturing a package includes placing a thick thermal decomposable polymer layer over metallization such as with a redistribution layer (RDL) (and solder and other metal protective layers if present) at a lower level dielectric or dielectric material layer on or over an IC package substrate core. The RDL and lower level dielectric material layer are to eventually become the bottom of a deep cavity to embed a die. A dielectric material formed of dielectric material layers then may be stacked over the polymer layer and the lower dielectric material layer. One or more of the stacked dielectric material layer may have metallization or metallization layers outside of the area reserved for the deep cavity. A laser then may be used to drill the deep cavity such as at least 50 microns deep, and by some forms 200 microns deep, while the polymer layer protects the metallization (and other layers) from the heating and skiving of the laser. Thereafter, the polymer layer may be removed by decomposition to expose the RDL, solder, and so forth for coupling to a die (which includes at least one die), such as an EMIB or EMIB-T. The die is then embedded in dielectric within the deep cavity.

The final assembled package will have a characteristic elongated gap around the RDL and die (at least in plan or top view) as a vestige of the polymer layer. Particularly, and due to laser tolerances, the laser drilling to the top of the polymer layer will have the tapered cavity sidewall terminate at the top of the polymer layer rather than the precise lateral end of the polymer layer. Thus, the polymer layer occupies an undercut or recess into the sidewall of the cavity when it existed and is emptied once the polymer layer is removed. The undercut is too deep to be filled when dielectric is deposited. The gap extends horizontally in an elongated direction at least within a dielectric material layer that is below the die and at the level of the RDL. The gap also extends horizontally around the metallization (or metallization pattern or RDL) under the die. The gap also may be tall enough to extend directly around the die as well (in the same horizontal plane). Regardless of the height of the gap, the gap will extend around both the metallization (or RDL) under the die and the die itself in a top view. The gap may be empty, or more precisely may hold air and/or other gases used during the manufacturing operations, and/or the gap may hold residual material from the polymer layer and/or other metal layers, such as a conductive seed layer of copper for example, that were previously deposited on the bottom of the deep cavity. This arrangement results in much less laser damage and/or IMC deterioration to the RDL, solder, and other metallization as well as reduced damage to the dielectric of the lower dielectric material layer supporting the RDL.

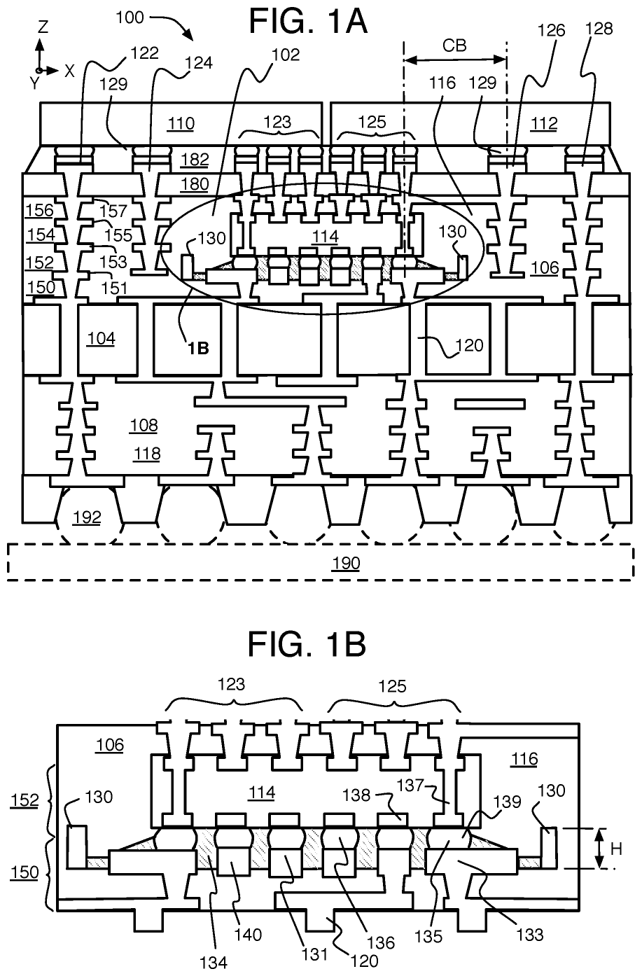

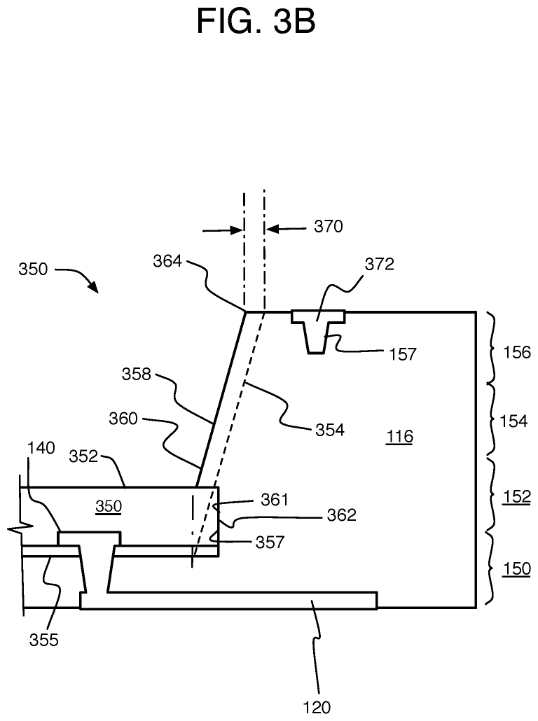

In addition, since the depth of the laser drilling merely needs to reach down to the top of the polymer layer, rather than extending down to the dielectric bottom of the cavity under the RDL, this shortened drilling depth results in a smaller horizonal component of the tapered sidewall of the deep cavity. This in turn reduces the width of the opening of the deep cavity at the top or upper surface of the dielectric (or upper-most dielectric material layer), thereby increasing the allowable minimum core-to-bridge distance. This is explained in greater detail below with FIGS. 1A and 3B.

To explain the core-to-bridge delta or distance, and in one example arrangement, the bridge die herein have bridge bumps coupling the bridge die to the RDL or metallization under the bridge die. Note the bridge bumps, and bridge interconnects, relevant here are under the bridge die, and do not refer to the bridge bump or interconnect above the bridge die. In contrast, core bumps are on core (or non-bridge) interconnects. The core interconnects extend from the bottom of the coupled dice and into the package substrate rather than to the bridge die. The term ‘core’ at least refers to “non-bridge” and is not meant to indicate any other hierarchy or priority of IC structure other than being in contrast to the bridge bump and bridge interconnects. This does not include any horizontal metallization, such as traces that may additionally couple a core interconnect to a bridge interconnect.

Additionally, the core-to-bridge distance or delta (or pitch) may include other distances as well and is used in its general sense herein. Thus, a core bump herein may be any bump on metallization that is external to a region that is, or was, occupied by the deep cavity, and more precisely outside of a position of the upper outer rim of the cavity. The distance also refers to a core bump that may be at or above the vertical level (or dielectric material layer) of the outer rim of the deep cavity (regardless of whether or not the outer rim still exists on the final product). The dielectric material layer that defines the outer rim may be on an upper-most dielectric material layer on a stack of dielectric material layers above the lower dielectric material layer. By another form, the core bump is at or above the upper-most metallization layer in the dielectric material forming the dielectric material layers regardless of which dielectric material layer has a metallization layer.

Also, the core-to-bridge distance as used herein is not limited to having bumps. The core-to-bridge distance (or pitch) as used herein is a horizontal measure from a conductive feature under the die embedded in the cavity and that couples the embedded die to the metallization or RDL at a bottom of the cavity (or lower dielectric material layer). Such a conductive feature can be a bump, cap, pad, trace, contact, via, pillar, and so forth. In this case, the ‘core’ in core-to-bridge distance as used herein also may refer to a vertically extending core interconnect that includes any of those conductive features, including a core bump, for coupling to another die or device, and that extends vertically outside of the upper out rim of the deep cavity, and through, or is located at, either an upper-most metallization layer or a dielectric material layer that forms (or formed) the upper rim of the cavity, and particularly the upper surface of such a dielectric material layer. By one form, this arrangement in turn results in the core interconnect or core bump being outside of the outer periphery of the embedded die and outer periphery of the RDL or metallization under the embedded die.

The bridge bump also may be omitted in such alternatives such as liquid metal interconnects and/or hybrid bonding (such as Cu to Cu bonding) by using plates or caps of a bridge interconnect that connect to each other directly rather than using solder under the embedded die. By any of these forms, the core-to-bridge distance may be considered a center to center (or edge to edge) measure between any combination of bumps, caps, pads, vias, and so forth on interconnects, with centers (or edges) that are arranged to align with a center (or edge) of a bump or other conductive feature on a device, such as a die.

By another approach, and whether or not the polymer layer is implemented over the RDL, an iterative laser drilling process may be used to reduce the total horizontal taper component of the deep cavity sidewall. This is accomplished by laser drilling after each dielectric material layer is deposited and then filling the cavity opening with a metal protective layer to act as a laser stop for the next dielectric layer deposited on the top of the stack. The laser is aligned to the same cavity dimensions at each iteration and may be aligned to a metallization pattern or RDL that is at the target depth of the bottom of the entire cavity. The result for a 200 micron deep cavity using an iterative approach can reduce the core-to-bridge distance to at most 15 microns for iterative CO2 laser, and at most 6 microns for iterative Excimer laser. Once the die is placed in the cavity and the cavity is filled with dielectric to embed the die, this arrangement will have a vertical array of the elongated gaps spaced one gap over another (or alternatively staggered with each or individual higher gap) and each extending partially or completely around the die and RDL in a top (see through) view. By one approach, the polymer layer can be used with the iterative laser process. By this example, this may result in the bottom gap being taller than the gaps above the bottom gap in the array of gaps.

By yet another alternative, the deep cavity may be formed by lithography in a dielectric of photo-imageable material (e.g., such as photo-imageable dielectric (PID), mold, glass, and so forth). The photo-imageable dielectric may be constructed of a stack of photo-imageable dielectric material layers over the RDL to be coupled to a die, and each layer may have metallization outside of the area of the cavity. By one form, the cavity is formed through the photo-imageable layers by positive photoresist lithography, and once the die is in place in the cavity, the cavity can be filled with a solder resist layer to protect the dielectric forming the cavity for the remaining fabrication operations and on the end product. By using the photo-imageable layer to form the deep cavity by lithography, the sidewalls of the cavity are vertical or substantially vertical, and the core-to-bridge distance may be reduced to at most 2 microns, and by another form 1 micron, and by yet another form, 0.5 microns. This alternative eliminates the need of the IMC protection and laser stops.

Referring now to FIG. 1A, an IC package 100 has a package substrate 102 with a substrate base (or core) 104 that divides the substrate 102 into a first or frontside 106 and a second (or reverse or back) side 108. The backside 108 may have interconnects to mount the IC package 100 on a board 190, such as a mother board, host board, and/or printed circuit board (PCB), and by one example, by second level interconnects (SLIs) 192. While the SLIs 192 are shown as solder balls, it is to be appreciated that the SLIs 192 may be any suitable interconnect architecture, including sockets or the like.

The frontside 102 has a die bridge arrangement where chips or dice including a left die 110 spaced laterally, in this example, from a right die 112 are coupled to each other through a bridge die 114 embedded in dielectric 116 on the frontside 106. By one form, the die is below the upper-most dielectric material layer 156 or at least below the upper-most metallization layer 157. This may include the die 114 being completely below those layers or extending at least partially below those layers. In this example, the left and right dice 110 and 112 are located above the dielectric 116. By the example form herein, the bridge die 114 electrically and/or physically couples the left die 110 to the right die 112. It will be understood that the term die refers to an integrated circuit (IC) component or chip, typically singulated from a wafer, that has one or more transistors and/or supporting circuitry to route electrical signals to the transistors, as well as any other IC components. Also, the dice 110, 112, and/or 114 may be monolithic dice, EMIBs or EMIB-Ts, chiplets as explained below, or any combination of these, and alternatively, the left and right dice 110 and 112 may be bridge dice as well. Many variations are contemplated. By yet other approaches, the die 114 may not be in a bridge arrangement as long as it can be partially embedded in the dielectric 116.

As to when one of the dice is a chiplet, the IC industry is continually striving to produce higher computational performance in smaller packages for use in various electronic products, such as computer servers, portable computers, electronic tablets, desktop computers, and mobile communication handsets. High performance computing products often now include one or more microelectronic packages that contain various combinations of semiconductor tiles, chips, chiplets, and dice that are integrated into one functional unit. These composite, or heterogeneous, IC device structures may include tiles, chips, chiplets, or dice created using diverse technologies and materials. The tiles, chips, chiplets, or dice may be stacked vertically, placed horizontally, or both. Connections between different devices may employ a variety of technologies, including direct bonding. Chiplets, rather than monolithic dice, disaggregate the circuits. Thus, the IC Package 100 may have multiple chiplets including multiple bridges where just one of the bridges is being shown here. The chiplet 114 may be communicatively coupled by interconnects (or bridge interconnects) to other dice 110 and 112 thereby itself forming an interconnect bridge between the dice 110 and 112. Also as mentioned, dice 110 and 112 also can be chiplets. By one form, however, the dice 110 and 112 are monolithic IC dice.

The term “chiplet” is used herein to refer to a die that is part of IC package 100 with dice 110 and 112, and here forming a complete IC in terms of application and/or functionality, such as a memory chip, microprocessor, microcontroller, commodity IC (e.g., chip used for repetitive processing routines, simple tasks, application specific IC, etc.), and system-on-a-chip (SoC). In other words, by one example form, chiplet 114 is an individual die (or IC die) that can be connected together to other chiplets to create the functionalities of a monolithic IC. By using separate chiplets, each individual chiplet can be arranged and manufactured optimally for a particular functionality. In this case, dice 110 ad 112 could be chiplets as well. For example, a processor core that contains logic circuits might aim for performance, and thus might require a very speed-optimized layout. This has different manufacturing requirements compared to a USB controller, which is built to meet certain USB standards, rather than for processing speed. Thus, by having different parts of the overall arrangement separated into different chiplets, each one optimized in terms of design and manufacturing, the overall yield and cost of the combined chiplet solution may be improved.

The connectivity between these chiplets (or a chiplet and monolithic IC dice) may be achievable by many different ways. For example, in 2.5D packaging solutions, a silicon interposer and through silicon vias (TSVs) connect dice at silicon interconnect speed in a minimal footprint. In another example as described herein, EMIBs have a silicon bridge or bridge die 114 embedded under the edges of two interconnecting dice 110 and 112 and facilitates electrical coupling between them. In a three-dimensional (3D) architecture, the chiplets are stacked one above the other, creating a smaller footprint overall, and could form one multi-layer bridge. Typically, the electrical connectivity and mechanical coupling in such 3D architecture is achieved using TSVs and fine pitch solder-based bumps (e.g., C2 interconnections could be used). The EMIB and the 3D stacked architecture also may be combined using an omni-directional interconnect (ODI), which allows for top-packaged chips to communicate with other chips horizontally using EMIB and vertically, using through mold vias (TMVs) which are typically larger than TSVs.

In some implementations that use chiplets, a composite chip may have a fill dielectric layer over back-end-of line (BEOL) metallization stack. A fill dielectric layer near the chiplet or bridge die here (in addition to the main or bulk dielectric 116, may fully surround chiplet sidewalls, embedding a chiplet within dielectric material, and may be the dielectric or may be a separately molded dielectric abutting dielectric 106. A fill dielectric may stabilize and strengthen the package 100, and/or provide a platform for higher BEOL metallization layers. In some implementations, a fill dielectric layer for a chiplet comprises an inorganic dielectric material, such as, but not limited to, amorphous and polycrystalline silicon oxides, in some cases having a higher k than inter-layer dielectric (ILD) materials. In some other implementations with chiplets, a fill dielectric layer comprises an organic material, such as, but not limited to, epoxy resins and epoxy resin composites.

Returning to the details of substrate 102, the substrate base or core 104 may be a base structure or layer itself that may be formed of one or more dielectric layers, metal layers, or a combination of both. A stacking direction is outward from the base layer 104 and opposite on the two sides 106 and 108. The substrate base 104 may be referred to as a substrate core herein.

The package substrate 102 may comprise a plurality of laminated dielectric layers with conductive metallization or metallization layers embedded therein. In the specific example implementations here, the package substrate 100 may be fabricated in a build-up process (e.g., a bumpless dielectric material layer (BBUL) package), whereby the package substrate 102 is formed by build-up of individual levels that each level referred to as a build-up or dielectric material layer and may have a dielectric film and a metallization plane or layer integral (or in other words, embedded within or on) with the dielectric film. In this example, and relevant here, frontside dielectric 116 has dielectric material layers 150, 152, 154, and 156 respectively with metallization layers 151, 153, 155, and 157. The backside dielectric 118 may have dielectric material layers as well. By the examples, herein, the dielectric material layers are formed of dielectric build-up films for example. The dielectric 116 materials, as mentioned with the chiplets, may comprise organic material, such as, but not limited to, polymers, epoxy resins and epoxy resin composites, ceramics, and so forth, which may be a mold or mold layers, of mold resin, such as a polymer resin with insert fillers. By other forms, the dielectric 116 may be inorganic dielectric material, such as, but not limited to, amorphous and polycrystalline silicon oxides, in some cases having a higher k than inter-layer dielectric (ILD) materials. The package substrate 102 also may comprise glass layers, or any other materials typical of electronic packaging architectures. The dielectric 116 may embed or cover all of the dice 110, 112, and 114 when desired rather than just the bridge die 114.

Metallization 120 may include metallization planes and vertical interconnects with vias, and/or pillars throughout the dielectric material layers on the substrate 100 including metallization extending through the substrate core 104 and within the dielectric material layers of the dielectric 116 and 118 on the front and backs sides 106 and 108 including the metallization layers 151, 153, 155, and 157. Thus, the metallization may include traces, contacts, pads, caps, pillars, and vias, for example, and including interconnect vias. The metallization, and by one form all of the metallization and conductive features, may be formed of copper, or an alloy of copper. By other forms, some or all metallization may be formed of other conductive materials, other metals, or metal alloys. Otherwise, the arrangement of the patterns of the metallization 120 on the substrate 102 are not particularly limited above that mentioned herein regarding the embedded die 114 and the position of the core interconnects relative to the outer rim of the cavity described below.

The metallization 120 may comprise conductive features fabricated from electrodeposited copper (a semi-additive process (SAP)) and/or etched (a subtractive process) through a lithographically defined photoresist mask. New layers may be added to both sides by the build-up package in cycles of dielectric film lamination and formation of a new metallization plane over the laminated dielectric film as described below.

As to the example bridge arrangement on substrate 100, and by one form, each die 110 and 112 has its own array of core interconnects 122, 124 on the left, and 126, 128 on the right respectively. The core interconnects 122, 124, 126, and 128 may have via pillars, caps, and/or pads with one or more metal or conductive features including a core bump 129, and whether the interconnects terminate in the front dielectric 116 or pass through the substrate core 104 for coupling to the board 190. In either case, such core interconnects may be provided for interconnection to another IC component such as a die, chip, device, board, substrate, or other such IC components in or on substrate 102. Otherwise, the interconnects 122, 124, 126, and 128 extend into substrate 100 through an upper-most dielectric material layer 156, and to an upper-most metallization layer 157. The core interconnects may be considered part of metallization 120. The interconnects 122, 124, 126, and 128 may have any desired arrangement of conductive features mentioned herein and are not particularly limited as with the other parts of metallization 120.

The bridge die 114, whether or not a chiplet, EMIB, or other die, may communicatively couple the left die 110 to the right die 112 by using bridge interconnects (or bridge vias) 123 from the top of the bridge die 114 to the left die 110 or bridge interconnects 125 from the top of the bridge die 114 to the right die 112. Herein, the bridge interconnects 123 and 125 may be considered upper bridge interconnects that may or may not be aligned with lower bridge interconnects 131 (FIG. 1B) at the bottom of the bridge die. The upper bridge interconnects 123 and 125 include any conductive features from the top of the die to the bottom of the dice 110 and 112. A solder resist layer 180 and an underfill 182 above the solder resist layer 180 may embed the bridge and core interconnects 123, 125, 122, 124, 126, and 128 between the upper-most dielectric material layer 156 and the dice 110 and 112.

Referring to FIG. 1B, metallization 120 couples to (or includes) metallization 140 under the die 114, and may be referred to as a redistribution layer (RDL), metallization layer, or metallization pattern that provides electrical signals and/or power to metallization 138 on the die 114. The die 114 shown here is an example EMIB-T with TSVs 137. The RDL 140 may include, or couple to, multiple lower bridge interconnects 131, here being six, and that may or may not be axial with the upper bridge interconnects 123 and 125. In the present example, The RDL 140 may have conductive features 133 such as caps or pads that are coupled to solder, here being bumps 136, which in turn are coupled to the metallization 138, such as contacts, caps, or pads, on the die 114. In the example of package 100, the core interconnects 122, 124, 126, 128, and the lower bridge interconnects 131 may have other configurations than that shown with any desired arrangement of pillars, pillar ends, caps, pads, vias, and any other conductive features.

The bottom bridge interconnects 131 establish the bridge (or bridge bump) point for the core-to-bridge distance, and specifically a most outer bottom bridge interconnect 139. By one form, the point for measurement (as shown by the dimension line on FIG. 1A) may be the center of the bridge bump 135 alone, or may be a center (or edge when measured edge-to-edge) of an RDL cap 133, and/or other die metallization when these components share a common center line (or edge location). The center of the RDL cap 133 may be used where the cap couples to other metallization above the RDL when no bridge bump is present, such as when solder is not being used. At a minimum, the dimension line should be placed at a center of the bottom bridge interconnect coupling the RDL 140 to the die metallization 138. A core-to-bridge delta or distance CB is between the bridge bump 135 of a bottom bridge interconnect 139 (closest to an outer periphery of the die 114 and RDL 140) and the core bump 129 that is closest to the die 114 without being within a region previously occupied by the deep cavity as described in detail below.

The conductive features of the interconnects 122, 124, 126, 128, and 131 may be formed of copper or other alloy or conductive material. The solder balls or bumps (or just solder) 136 as well as any other bumps herein may be formed of Sn, or may comprise Sn, such as with SnCu, or may comprise a compound with In such as SnIn or SnInCu, but otherwise may be any known solder that adequately forms connections on IC die and package substrates. The bridge interconnects 122, 124, 126, 128, and 131 also may have one or more barrier layers, diffusion barrier layers, IMC barrier layers, or other types of layers. An underfill 134 and/or adhesive filler with a material such as CUF (capillary underfill or MUF (mold underfill) material may be placed between the die 114 and the dielectric material at the lower dielectric material layer 150, and over the RDL 140.

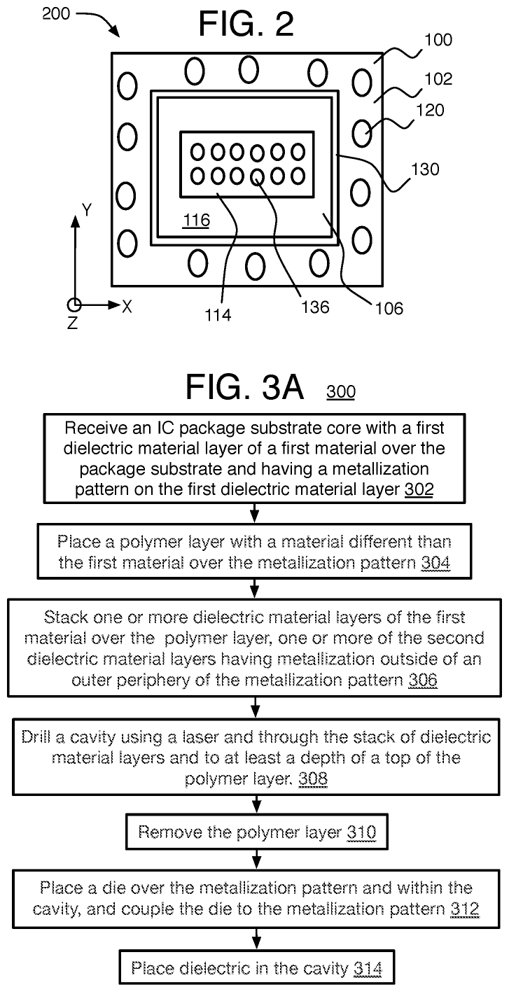

Referring to FIGS. 1A, 1B and 2, the package substrate 102 is fabricated by using a polymer layer to protect the RDL or metallization pattern 140 when a laser is used to drill a cavity (not shown) to place the die 114 in the cavity. The polymer layer is removed before placing the die 114. Once the polymer layer is removed and the cavity is filled in to embed the die 114, nothing may remain of the polymer layer in the final product as shown on package 100. A vestige in the form of a gap 130, however, does remain because the filling in of the cavity may not fill all locations previously occupied by the polymer layer. Specifically, the laser drilling of the cavity results in a deep undercut that is occupied by the polymer layer that cannot be filled when depositing dielectric into the cavity. By one form, the gap 130 has an elongated direction around the die 114 and RDL 140 as shown in see-through top view 200 (FIG. 2). The elongated gap 130 may completely encircle the die 114 and RDL 140, and is shown as a rectangle in top view 200 but many other shapes could be formed that correspond to the outer periphery of the polymer layer. This may include quadrilateral, polygonal, other curved or circular shapes, and other irregular shapes. The gap 130 may have an elongated direction around the metallization pattern 140 or die 114 and a cross-section that is transverse to the elongated direction, and the transverse cross section is shown as rectangular as well on FIGS. 1A and 1B. The actual shape of the transverse cross section may be any enclosed shape or partially enclosed shaped including irregular shapes. The gap 130 may have a height H on the transverse cross-section and may have a height of 5 to 50 microns by one form, and 35 to 45 microns by another example, and up to 200 microns by yet another form. By one form, the gap 130 extends horizontally in the lower dielectric material layer 150 and around the metallization pattern 140, but may be tall enough to also extend into the dielectric material layer 152 (as shown in FIG. 1B) and extend around the die 114 (in the same horizontal plane as the die). Otherwise, the gap 130 extends around the die in top view, which generally includes a see-through top view herein. The gap 130 may hold air and/or other gases as well as residual polymer material from the polymer layer and/or other materials such as a metals from left over material from a seed layer for example.

Also, it will be appreciated that the structure of any of the implementations, herein, including bridge and cavity structure, may be provided on the backside instead of, or in addition to, the front side of the substrate core.

Referring to FIG. 3A, an example process 300 of manufacturing an IC package is provided according to at least one of the implementations herein. Process 300 includes operations 302 to 314 generally numbered evenly, and electronic systems, devices, packages, and/or package substrates 100 of FIGS. 1A, 1B, 2, and 3B may be referred to herein where appropriate.

Process 300 may include “receive an IC package substrate core with a first dielectric material layer of a first material over the package substrate and having a metallization pattern on the first dielectric material layer” 302, and this refers to at least one die and that may or may not be a bridge die as long as it can be at least partially placed in a cavity drilled by a laser. The metallization pattern can have many different arrangements, and may be an RDL that routes power into the die as described above. The metallization pattern may be located on the dielectric material layer where a bottom of a cavity is to be formed, and the dielectric material layer with the metallization pattern may be referred to as the lower dielectric material layer. The lower dielectric material layer as well as the other dielectric material layers may have dielectric material as described above, and metallization layers as described above with substrate 102. The metallization pattern may have conductive features such as caps or pads for coupling to the die, and may or may not be provided with solder caps on caps or pads of the metallization pattern. The solder may be made of tin or other material mentioned above for example, and a protective layer of nickel may be either over the solder when present or directly on the caps or pads of the metallization pattern.

Process 300 may include “place a polymer layer with a material different than the first material over the metallization pattern” 304. This operation may involve depositing the polymer layer over the metallization pattern and solder caps or other protective layers when present. The polymer layer is relatively thick and may have a thickness of 5 to 200 microns by one form, and 5 to 50 microns by another form. By one example, the polymer layer is 35-45 microns thick. The thickness of the polymer layer may be selected by factoring the height of the metallization pattern (or RDL) such as 10 microns, a 5 micron buffer, and then a typical 10 or 20 micron operational depth tolerance of the laser depending on the type of laser used (and specific laser product being used when the tolerance can be determined). The polymer should be at least sufficiently thick so that even with the maximum tolerance (or variation) of the laser, the laser will not cut into the metal layers under the polymer layer.

By one form, the polymer layer is decomposable and has a material of Polynorbornene (with a breakdown temperature of 240-400 deg C), Polyalkylcarbonates (with a breakdown temperature of 200-300 deg C), and/or Polyaldehydes (with a breakdown temperature of 120-200 deg C). In implementations, acrylates and quinones can be added to sacrificial polymer blends to make them photo-definable. It should be noted that the alkaline robustness of these polymers make them useful for various thermal photo-definable processes, such as backend bump plating.

Process 300 may include “stack one or more second dielectric material layers of the first material over the polymer layer, one or more of the second dielectric material layer having metallization outside of an outer periphery of the metallization pattern” 306. Here, the remaining dielectric material layers may be stacked on the polymer layer including an upper-most dielectric material layer where the laser will enter the stack to drill the cavity. By one form, four dielectric material layers are present as in package substrate 102, but any number of dielectric material layers may be used as needed. The dielectric material layers may be stacked, by one example, by repeating cycles of dielectric material layer deposition, laser drilling or etching of via holes, metal plating (such as copper plating) over the holes to form vias, and resist pattern and etching to form pads and/or traces over the vias. More detail is provided below.

The process 300 may include “drill a cavity using a laser and through the stack of second dielectric material layers and to at least a depth of a top surface of the polymer layer” 308. A laser such as a CO2 laser or Excimer drill may be used to skive a deep cavity down to a top or top surface of the polymer layer. This depth may be at least 50 microns, or 200 microns by some examples. By another example, the drilling depth is over 100 microns or 200 microns to cover EMIB-Ts that are respectively 100 to 200 microns tall. The width of the upper outer rim of the cavity on an upper-most dielectric material layer may be at least 500 microns. Also, the upper outer rim of the cavity, and the cavity bottom (whatever forms the bottom of the cavity to the bottom periphery of the cavity sidewall), may be rectangular in the current example.

Referring to FIG. 3B, the substrate 100 here has a polymer layer 350 over a metallization pattern (or RDL) 140 coupled to substrate metallization 120 on the dielectric 116. A seed layer 355 extends under the polymer layer 350 as well. A deep cavity 358 is laser drilled through dielectric material layers 150 to 156 from the upper-most dielectric material layer 156 that forms an upper outer rim 364 of the cavity 358 and down to a top 352 of the polymer layer 350. The cavity sidewall 360 terminates at the top surface 352 rather than the lateral end 362 of the polymer layer due to the manufacturing tolerance of the laser. This results in the polymer layer 350 occupying a deep undercut 357 at or into the sidewall 360. The undercut 357 may extend all the way around the polymer layer, and in turn the metallization pattern or RDL 140, at an outer periphery 361 of the cavity 358.

In addition, since the depth of the drilling is shorter with the polymer layer 350 (compared to a cavity depth and sidewall drilled without the polymer layer 354 shown in dashed line), and assuming the same cavity bottom width needs to be maintained to clear the metallization pattern and die, the result is reducing the width of the upper outer rim 364 of the cavity 358 by a distance 370. This extra distance 370 then adds more usable area for metallization or interconnects 372 through or at the upper-most dielectric material layer 156 or an upper-most metallization layer 157.

At this point in the process, the polymer layer 350 will have served its purpose protecting the underlying layers from direct damage by the laser as well as reducing IMCs on the copper and solder layers under the polymer layer. Thus, the polymer layer now can be removed.

Process 300 may include “remove the polymer layer” 310. This may be performed by decomposing the polymer layer by applying heat (or baking) to the breakdown temperatures mentioned above as needed and depending on which material was used. By an alternative form, wet chemical stripping could be performed where a resist layer is placed over the polymer layer, and lithography is then used to strip the polymer layer away.

This operation also may include etching away any protective layer on the metallization, such as a thin nickel layer to be removed to expose the metallization pattern for coupling to a die, or to etch away the seed layer 355 at the bottom of the cavity and over the lower dielectric material layer 150.

The result is that the overhang 357 is now empty with just air or other manufacturing gases, and/or may have residual amounts of the polymer material and or other metal layers such as the seed material.

Process 300 may include “place a die over the metallization pattern and within the cavity, and couple the die to the metallization pattern” 312, where a die, which may be a bridge die, chiplet or other type of die, may be attached to the metallization pattern through solder for example, although non-solder coupling may be performed as well. This operation also may include placing an underfill, such as by capillary action, between the die and the metallization pattern and lower dielectric material layer.

Process 300 may include “place dielectric in the cavity” 314. The cavity then may be filled or at least partially filled with dielectric, which may be the same material as the dielectric material layers and that encapsulates the die. Once the cavity is filled and the die is encapsulated or embedded (or at least partially embedded), the package substrate is ready for stacking more layers and or mounting more dice on the substrate, such as mounting the dice for coupling to the top of the now embedded bridge die. It will be understood that when the die is shorter than the cavity height, the dielectric may completely embed the die, but when the die is tall and extends above the height of the outer upper rim of the cavity, dielectric material that is the same or similar material as the dielectric material layers disclosed here may fill the spaces in the cavity between the die and the sidewalls of the cavity. In this case, another dielectric layer, which may or may not be the same material as the dielectric material layers, maybe placed over the top of the die.

Since the undercut 357 is relatively deep, the filling of the cavity results in the forming of the gap (FIGS. 1A-2) around the metallization pattern and die and left by the removal of the polymer layer.

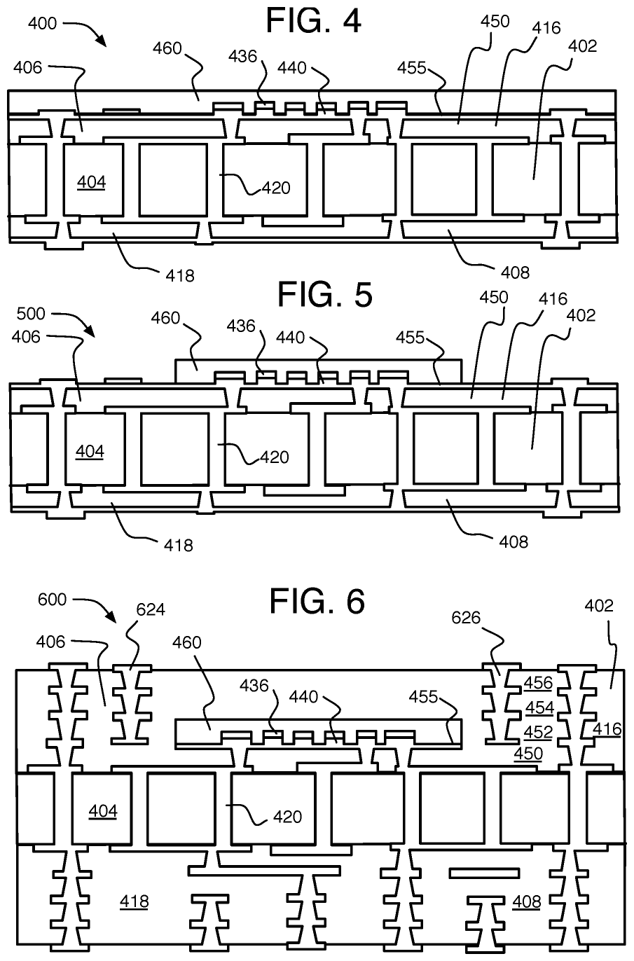

Referring to FIGS. 4-10 for more detail, a process for assembling an IC package is shown, and particularly for assembling an IC package substrate with an embedded die having lower IMC generation at the metallization pattern under the die, in accordance with at least one of the implementations herein. The process stages numbered 400 to 1000 by multiples of 100 are shown in FIGS. 4-10 merely as one example process, and it will be appreciated that many different process flows may be used in order to provide such an embedded die interconnect layer as described herein.

Referring to FIG. 4, an IC package substrate intermediate manufacturing stage 400 shows a package substrate 402 with a substrate core 404, a first or front side 406 with a dielectric 416 with a first or lower dielectric material layer 450, and a second or backside 408 with a dielectric 418. The dielectric material layers may be those mentioned above. A seed layer 455, here being copper, is deposited over the dielectric material layer 450, and the metallization pattern (or RDL) 440, as well as other metallization such as caps or pads, is formed thereon by using a resist pattern, such as laminated dry film resist (DFR), and mask to shape the resist into a desired pattern. Copper plating is then used to form the metallization pattern (or RDL) 440 in the desired pattern. Solder caps 436 may be formed on the caps, pads, and so forth of the metallization pattern 440 repeating the same process operations. By an alternative form for any of the implementations herein, and to avoid the laser melting the solder on the RDL, the solder may be patterned on the silicon (or die) side instead. This may reduce taper and time for drilling the deep cavity.

Thereafter, the polymer layer 460 may be deposited over the metallization pattern 440 and solder caps 436 as well as the seed layer 455 and lower dielectric material layer 450. The polymer layer 450 here is as described with process 300 above, and is a thick decomposable layer to protect the solder plates 436, metallization pattern 440, seed layer 455 and dielectric material layer 450 from the laser, whether from physical damage or IMC generated by heat.

It should be noted that the elements of the substrate are numbered similarly to that of FIG. 1 where possible, and where elements are already adequately described on package 100, the description is not repeated for FIGS. 4-10.

Referring to FIG. 5, in a stage 500, a selective dry etch may be applied through a shadow mask, or lithography pattern, in order to reduce the area of the polymer layer 460 to just over the cavity or bridge region.

Referring to FIG. 6, in a stage 600, the seed layer 455 is patterned and etched out, and the remaining dielectric material layers also are patterned and stacked in a repeating process of dielectric material layer deposit, laser drilling for via openings, and then semi-additive electroplating (SAP) of copper or other metal over the dielectric, such as by using semi-additive electroplating processes through lithographically-defined openings in a photoresist mask. In the example shown, stacked dielectric material layers include the lower dielectric material layer 450, middle layers 452 and 454, and upper-most dielectric material layer 456 and have additional metallization including the construction of core interconnects 624 and 626 that are the closest interconnects to cavity or bridge area with the metallization pattern 440 and polymer layer 460 now embedded under the dielectric material layers 450, 452, 454, 456.

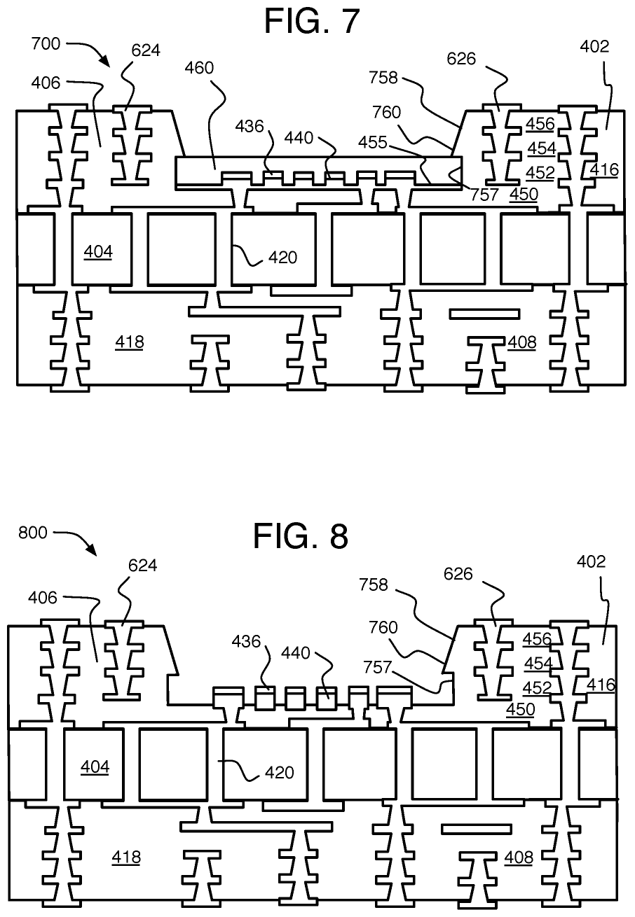

Referring to FIG. 7, in a stage 700, a laser drill is used with skiving to drill through dielectric material layers 452 to 456, and form a wide and deep cavity 758 with a tapered sidewall 760. The drilling is performed down to the polymer layer to expose the polymer layer 460. As mentioned, the manufacturing tolerance (or other variations) of the laser may cause the laser to cut into the polymer layer 460 itself. Thus, the polymer layer 460 is thick to prevent or reduce the laser and laser heat from reaching the layers 440, 436, and 455 under the polymer layer 460, as described above by one example, with the polymer layer 460 being 15 or 25 microns thick above the metallization pattern 440, solder plates 436, and seed layer 455, and/or whatever has the highest point on the metallization to be under the polymer layer, and with a total thickness of 35-45 microns, by one example. The drilling results in the polymer extending into (or beyond) the sidewall 760 and into an undercut 757 that extends around the polymer layer 460 and metallization pattern 440 at the periphery of the bottom of the cavity 758. The seed layer 455 also may extend into the undercut 757. As shown, the undercut 757 may have the same or close to the same height as the polymer layer 460.

Referring to FIG. 8, in a stage 800, the polymer layer 460 may be removed by decomposition using heat as described above or by alternative techniques such as Wet processing using conventional stripping agents or thermal decomposition The seed layer 455 also may be removed by dry or wet etching.

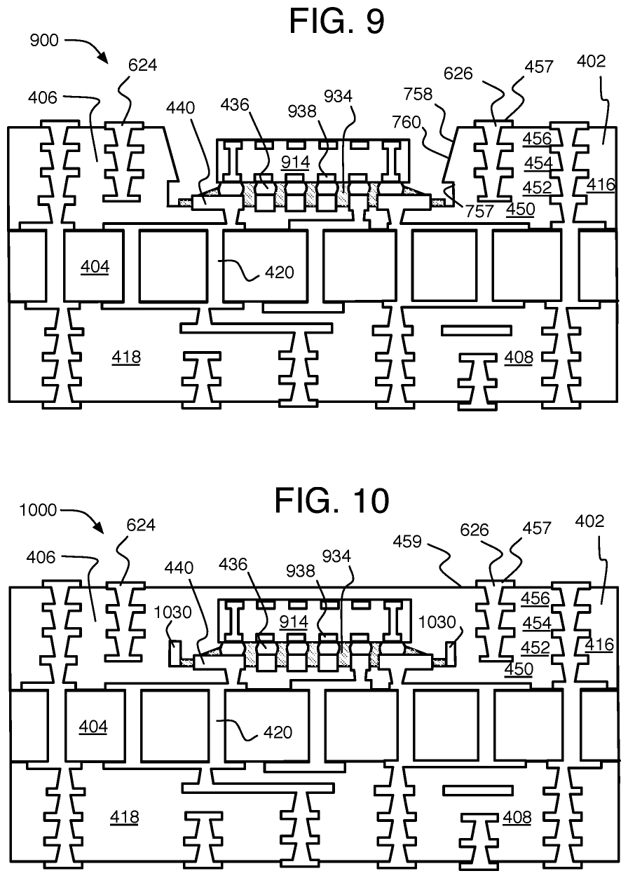

Referring to FIG. 9, in a stage 900, a die 914, such as a chiplet, bridge die, EMIB, EMIB-T as shown here, and so forth may be attached to the metallization pattern 440 by coupling the metallization 938, such as caps, on the die 914 to the solder 436, which now are bridge bumps on lower bridge interconnects including caps of the metallization pattern 440. The die 914 is entirely, or at least partially, placed lower than the upper-most metallization layer 457 in the dielectric material 116. A capillary action, or other type, underfill 934 may be placed between the die 914 and the metallization pattern 440 and lower dielectric material layer 450.

Referring to FIG. 10, in a stage 1000, the cavity is at least partially filled, and here completely filled, with dielectric material such as those described above or the same material as the dielectric material layers 450 to 456. The cavity 758 then no longer exists, and all that remains as a vestige of the polymer layer 460 is a gap 1030 where the filler could not reach due to the depth of the gap 1030. The gap 1030 is the same or similar as that described above with gap 130 on FIGS. 1A-2 and 3B. Since the tapered sidewall of the cavity is closer to the die 914 and metallization 440 compared to without the use of the polymer layer 460, there is more core-to-bridge distance for more or larger metallization at a top surface 459 of the upper-most dielectric material layer 456 or upper-most metallization layer 457. The package 400 is now ready for adding the upper dice above the die 914 for a bridge arrangement and any upper layers above upper-most dielectric material layer 456. An example of the complete package may be package 100 shown in FIG. 1.

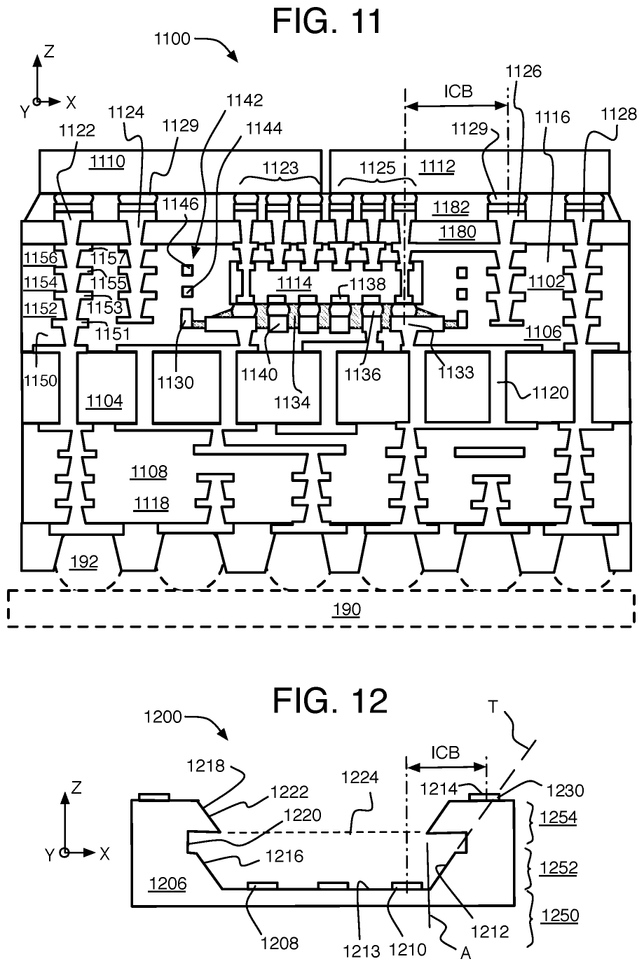

Referring to FIG. 11, an alternative package 1100 is the same or similar to that of package 100, such that the elements or components on the package 100 in both FIGS. 1A and 1B that are numbered similarly to that on package 1100 are the same or similar elements or components on package 1100, and need not be described again.

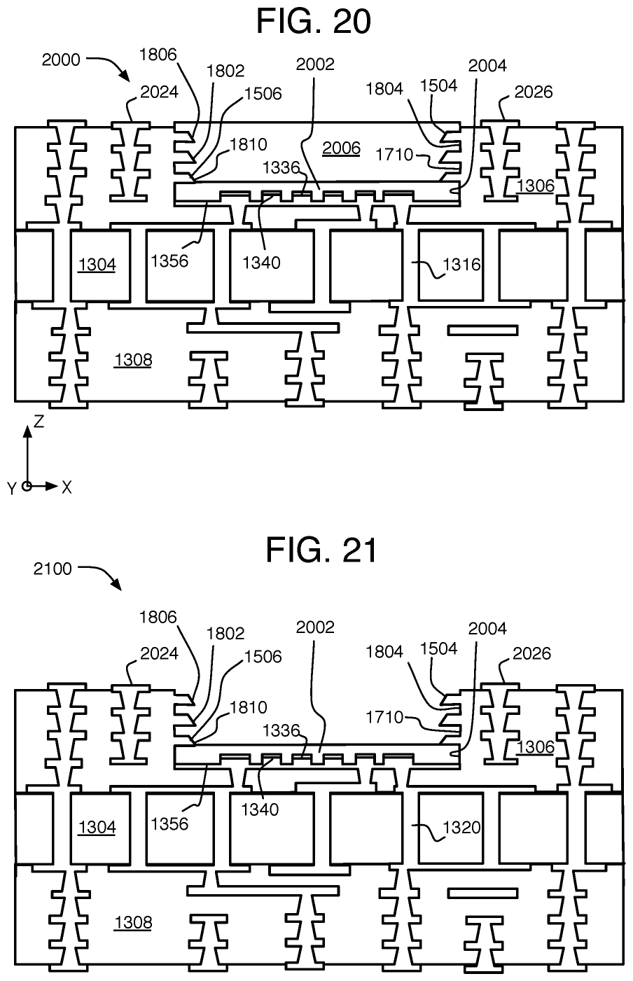

Package 1100, however, was fabricated using an iterative laser approach or method that generates an array 1142 of gaps 1130, 1144, and 1146 rather than a single gap 130 as with the polymer layer described above. Each of the gaps in the array 1142 may have the same or similar shape as gap 130. The gaps in the array 1142 are spaced from each other vertically and extend around the metallization pattern (or RDL) 1140 and the die 1114 in plan or top view. While the array 142 may be a linear array where each gap is directly, or substantially directly, one over the other as shown, the horizontal position of the gaps may be staggered from one level to another between any of the gaps. While three gaps are shown, there may be more or less gaps, including one gap using the iterative process described herein. One or more of the gaps may be in each of the dielectric material layers 1150, 1152, 1154, and 1156, or the gaps may be spread throughout the dielectric material layers unevenly, where one or more of the dielectric material layers do not have a gap, and another dielectric material layer has more than one gap. By one form, at least one of the gaps in the array 1142 may extend directly around (in the same horizontal plane) as the die 1114. This iterative laser approach also can be used with the polymer layer as described above with package 100, and provided in detail below with FIGS. 20-21.

Referring to FIG. 12, an iterative laser drilling process may be used to reduce the total horizontal taper component of the deep cavity sidewall. An example simplified substrate 1200 to explain the iterative process has a dielectric 1206 with metallization pattern (or RDL) conductive features 1208 and 1210 at a bottom of a cavity 1213 and at a lower dielectric material layer 1250, and with higher dielectric material layers 1252 and 1154 over the lower dielectric material layer 1250. The metallization pattern features 1208 and 1210 may be those as described with metallization pattern 1140 and 140 (FIG. 1A-1B). The features 1208 and 1210 are at a target depth that is a bottom 1213 of the cavity 1212, and may be considered bridge pads of interconnects, or bridge bump locations. Interconnect or core bump cap or pad location 1214 may be part of an upper-most metallization layer 1230 of the upper-most dielectric material layer 1254.

For the iterative process, rather than build-up of all of the layers and then perform a single laser drilling at a very wide taper T as shown, dielectric material layer 1252 may be laser drilled after being deposited on dielectric material layer 1250, but before dielectric material layer 1154 is deposited over dielectric material layer 1254. The drilling creates sidewall 1216 of the cavity 1212. The cavity 1212 is then filled with a metal protective layer, such as copper to act as a laser stop for the next dielectric layer deposited on the top of the stack. This occurs while the protective layer material, such as copper, is also deposited to form adjacent vias and/or other metallization outside of the area of the cavity 1212. The metal is deposited to be higher than the dielectric material layer 1252, here to the dashed line 1224, and may be controlled by a patterned resist layer.

Thereafter, the next higher dielectric material layer 1254 is deposited, and then drilled to the protective layer 1224 creating cavity upper sidewall 1218. At each iteration, the drilling is performed by aligning the laser with the same metallization or RDL pattern location 1210 at a target bottom of the cavity 1212 for example to obtain the same size opening of the cavity 1212 for each iteration as shown by the alignment line A. Thus, the laser drilling will form the same (or similar) size opening with an upper tapered sidewall 1218 at each layer, thereby creating a cavity sidewall 1222 with a toothed or grooved appearance, and where the upper taper sidewall 1218 is on a tooth or overhang, and ideally directly over any lower tapered sidewalls 1216. This significantly reduces the iterative core-to-bridge delta or distance (ICB) versus without the use of the iterations. The protective material or metal remains with each iteration, thereby forming a stack of the protective material filling the cavity 1212.

This arrangement also creates an undercut 1220 in the dielectric build-up material where the metal 1224 was higher than the lower dielectric material layer 1252. The stack of protective layer material (or copper for example) is then etched away once the top dielectric layer, drilling, and filling with the conductive material is complete. The result for a 200 micron deep cavity using an iterative approach can reduce the core-to-bridge distance to at most 15 microns for iterative CO2 laser, and at most 6 microns for iterative Excimer laser. Once the die is placed in the cavity and the cavity is filled with dielectric to embed the die, the undercuts are too deep to be filled and remain as gaps as described with gaps 1130, 1144, and 1146 in a vertical gap array 1142. By one Approach, the polymer layer can be used with the iterative laser process, and in this case, this may result in the bottom gap 1130 being taller than the higher gaps 1144 and 1146 in the array 1142 of gaps.

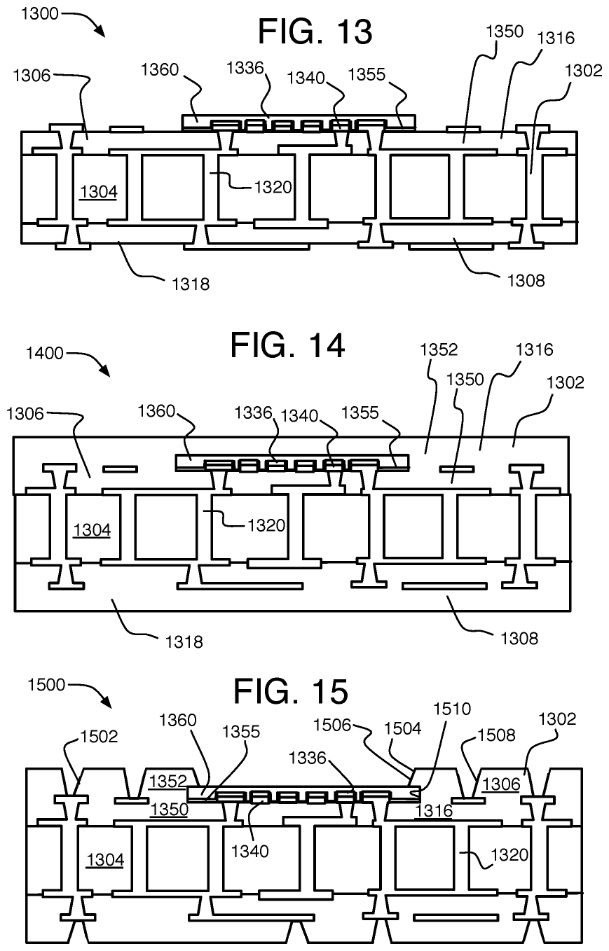

Referring to FIGS. 13-19 for more detail, a process for assembling an IC package is shown, and particularly for assembling an IC package substrate with an embedded die using an iterative laser drilling process to form the cavity for the die, in accordance with at least one of the implementations herein. The process stages numbered 1300 to 1900 by multiples of 100 are shown in FIGS. 13-19 merely as one example process, and it will be appreciated that many different process flows may be used in order to provide such an embedded die interconnect layer as described herein.

Referring to FIG. 13, an IC package substrate intermediate manufacturing stage 1300 shows a package substrate 1302 with a substrate core 1304, a first or front side 1306 with a dielectric 1316 with a first or lower dielectric material layer 1350 of dielectric of the materials described herein. Most of the structure here is the same or similar to that of stage 400 (FIG. 4) where the same or similar part or element is numbered similarly. Thus, these elements need not be re-described. The package substrate 1302 here, however, does have a metal protective layer 1360 (that may be referred to as a first or base protective layer) that is plated around the metallization pattern 1340 (and solder 1336 when present) by using semi-adaptive process (SAP) as mentioned above. The resist pattern and etching maintains the protective layer 1360 in the vicinity of the metallization pattern 1340 and the target location of a deep cavity.

Referring to FIG. 14, in a stage 1400 a next dielectric material layer 1352 is deposited or laminated over the lower dielectric material layer 1350 and the protective layer 1360.

Referring to FIG. 15, in a stage 1500 the laser drill drills into dielectric material layer 1352 using skiving and to a depth of the protective layer 1360, which forms a cavity 1504 with a tapered sidewall 1506. Via holes 1502 outside of the cavity also may be drilled or dry etched to expose the metallization 1320 for coupling thereto.

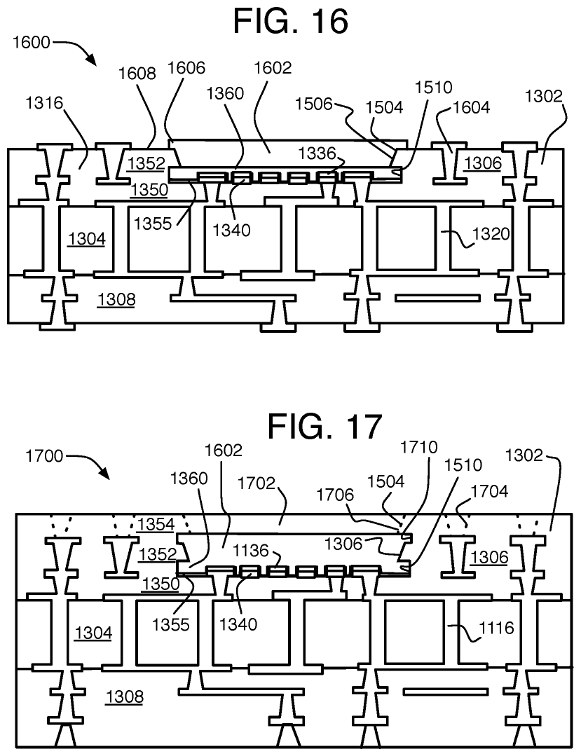

Referring to FIG. 16, in a stage 1600, another protective layer 1602 is deposited to fill the cavity 1504 and over the base protective layer 1360. This may be accomplished by lithography as well, where a resist is patterned and then filled with electroplating. The vias 1604 outside of the cavity area may be plated at the same time. The protective layer 1602 is patterned to have a flange 1606 over the top 1608 of the dielectric material layer 1352 to adequately protect the edge of the cavity on a current dielectric material layer.

Referring to FIG. 17, in a stage 1700, another lamination or dielectric material layer 1354 is deposited, and then another portion 1702 of the cavity 1504 is drilled to form a sidewall 1706 as well as drilling or dry etching holes 1704 for vias outside of the cavity area when desired. The cavity is then filled with another protective layer. This is repeated as many times as desired and depending on the dimensions of the cavity and thickness of each dielectric material layer as well as other factors.

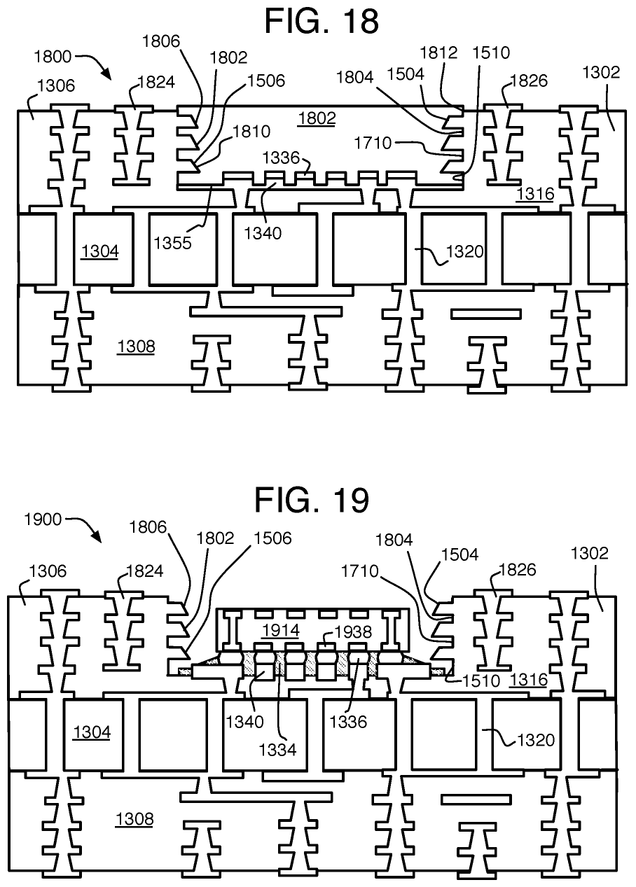

Referring to FIG. 18, in a stage 1800, an upper-most dielectric material layer 1356 has been completed and the cavity 1504 is now filled with a mass 1802 of protective layer metal materials, such as copper as mentioned above. The cavity 1504 also now has a set of teeth 1810 formed of 1810 formed by vertically aligned tapered cavity sidewalls 1506, 1802, and 1806 divided from each other by undercuts 1710 and 1804. Metallization 1320 outside of the outer upper rim of the cavity 1504 may include core interconnects 1824 and 1826 that are closest to the outer upper rim 1812 for measurement of the core-to-bridge distance.

Referring to FIG. 19, in a stage 1900, the metal or copper mass 1802 may be removed by etching such as by an alkaline etchant, CuC₁₂/HCL solution, or many other etchants to provide space for attachment of a die 1914 with metallization such as caps or pads 1938. The seed layer 1355 also may be etched by dry etch. An EMIB-T is shown as the die 1914 in this example, but may be other types of dies including chiplets as explained above. The attachment of the EMIB-T to the metallization pattern 1340 including coupling to the solder 1336 and placing underfill 1334 may proceed the same as with stage 900 (FIG. 9).

In the present example, the following stages of covering of the die 1914 and completing of the package substrate 1302 results in the package substrate 1102 (FIG. 11). As shown, the filling of the cavity 1504 results in the gap array 1142 (FIG. 11) due to the depth of the undercuts 1510, 1710, and 1804. The iterative core-to-bridge delta (ICB) also is significantly reduced as mentioned, and compared to the core-to-bridge delta without the iterative process.

Referring to FIGS. 20-21, in a stage 2000, instead of the base metal protective layer, a polymer layer 2002 is used for protection over the metallization pattern (or RDL) 1340, solder 1336, and seed 1355. The operations of stages 1300 to 1900 are the same or similar except that polymer layer 2002 fills a lowest undercut 2004 rather than a metal layer. Then in stage 2100, and to place a die in the cavity, a metal mass 2006 may be removed by etching down to the top of the polymer layer 2002. The polymer layer 2002 then can be removed by heat decomposition as explained above as well with process 300 and/or stage 800. The result is that the bottom gap 1130 on FIG. 11 will be formed from the undercut 2004 once the polymer layer 2002 is removed and the cavity 1504 is filled, and the bottom gap 1130 may be the tallest of the gaps in the gap array 1142 due to the thickness of the polymer layer 2002. Note, however, there may be other reasons that the bottom gap 1130 is the tallest gap, such as an RDL that has a very thick profile and will create a tall bottom gap even when the metal protective layer is used at the bottom of the cavity. Many other variations are contemplated.

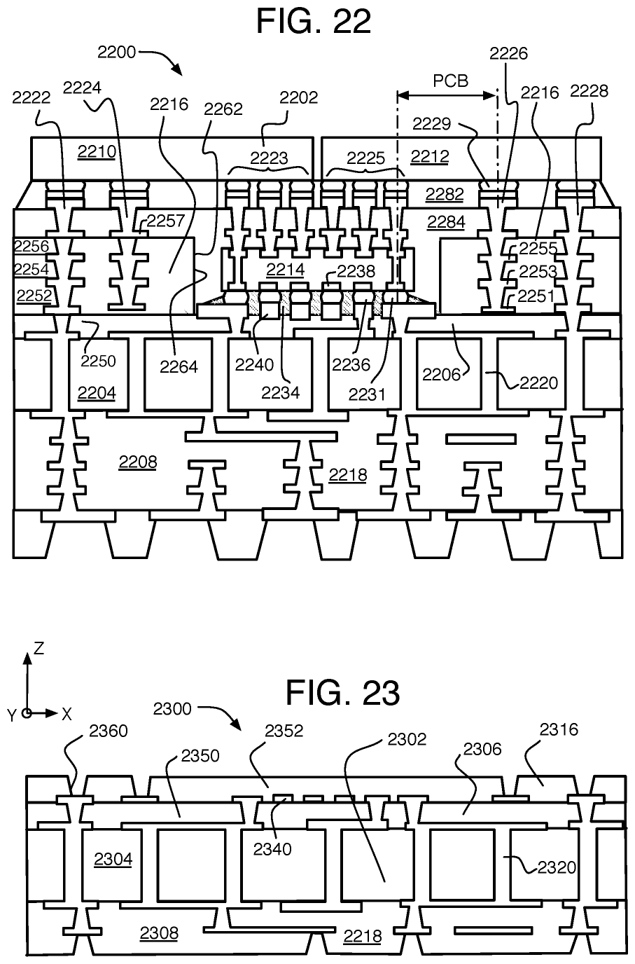

Referring to FIG. 22, an alternative package 2200 has some of the same or similar features or elements as that of package 100, such that the elements or components on the package 100 in both FIGS. 1A and 1B that are numbered similarly to that on package 1100 are the same or similar elements or components on package 1100, and need not be described again.

Thus, package 2200 may have the same or similar substrate core 2204, first or lower dielectric material layer 2250 formed of a dielectric of the materials described above, and bridge die arrangement with bridge die 2210, 2214, and 2216, and the bridge and core interconnects already described with package 1100. Different here, however, the remaining dielectric material layers 2252, 2254, and 2256 may be formed of photo-imageable material to form a bulk photo-imageable dielectric 2216. The photo-imageable material may be photo-imageable dielectric (PID), photo sensitive mold, glass, and so forth. A photo-image core-to-bridge distance (PCB) also is shown from core interconnect 2226 closest to the recess 2262 and bridge interconnect or bump 2231.

By one example form, the photo-imageable material also may have a cross-linking (or curing) inhibitor to prevent or limit curing due to many of the fabrication stages that may involve heat after the photo-imageable materials are in place but before the cavity is to be removed. Once the photo-imageable is cured, it cannot be used for lithography. Such curing inhibitor may be removed from the photo-imageable material just before the cavity is to be formed. By another form, the inhibitor may be omitted when no heat operations with temperatures that affect the photo-imageable material are being performed in a vicinity of the photo-imageable dielectric material layers while the photo-imageable dielectric material layers are being stacked.

By another form, the photo-imageable material also may have an anti-shrinking material such as filler, which can be Silica fillers, hollow fillers, disc fillers, BaSO4 fillers and so on. For this application, the additive amount may be low to avoid impacting patterning results, such as less than 5-10 wt %.

Once a stack of the photo-imageable dielectric material layers 2252 to 2256 is complete, a deep cavity 2262 with vertical or near vertical sidewalls 2264 can be formed through the dielectric material layers and in the photo-imageable dielectric 2216 by using photoresists. Once the die 2214 is attached and placed in the cavity 2262, a different dielectric material may be placed over and/or around the die 2214 to embed the die, such that cavity sidewalls 2264, albeit with the cavity 2262 filled, still exists on the final package substrate 2202. By one form, the die 2214 is embedded by solder resist layer 2284 that is deposited within the cavity as well on the upper-most dielectric material layer 2256 in order to protect the photo-imageable dielectric 2216 from subsequent fabrication operations, and particularly from heat, dust, moisture, and UV exposures. A solder resist 2284 may be over the photo-imageable dielectric 2216. The solder resist material can be a mixture of epoxy and acrylic components. The acrylic component may be able to crosslink under UV exposure and an epoxy component can cure under a thermal bake afterwards. The solder resist normally has fillers like Silica to improve its mechanical properties. The solder resist can have a thickness that can vary from 5 microns to 30 microns.

The package can then be completed with the two dice 2210 and 2212, and underfill 2282 between the dice 2210 and 2212 and the photoresist layer 2284. By one form, the photo-imageable system and method can achieve photo-imageable core-to-bridge (PCB) distance of at most 2 microns, and by one form, 1 micron, and by another form, 0.5 microns.

Referring to FIGS. 23-27 for more detail, a process for assembling an IC package is shown, and particularly for assembling an IC package substrate with an embedded die using a photo-imageable material to form the cavity for the die, in accordance with at least one of the implementations herein. The process stages numbered 2300 to 2700 by multiples of 100 are shown in FIGS. 23-27 merely as one example process, and it will be appreciated that many different process flows may be used in order to provide such an embedded die interconnect layer as described herein.

Referring to FIG. 23, an IC package substrate intermediate manufacturing stage 2300 shows a package substrate 2302 with a substrate core 2304, a first or front side 2306 with a first or lower dielectric material layer 1350 of a dielectric or a material described herein, and metallization 2320 on the substrate core 2304 and lower dielectric material layer 2350. Much of this lower level structure closer to the substrate core is the same or similar to that of stage 400 (FIG. 4) and need not be described again here. The package substrate 2302 here, however, has the metallization pattern (or RDL) 2340 without any metal protective layers and without solder. The metallization pattern 2340 has already been patterned by a resist and dry or wet etched, and the seed has already been etched away as well.

A photo-imageable dielectric material layer 2352 may be a PID forming dielectric 2316 and that has been laminated over the metallization pattern 2340 and lower dielectric material layer 2350. The backside 2308 may be stacked with another dielectric material layer of dielectric material such as those mentioned above, and this may be repeated with each layer on the front side 2306. Both sides then may be drilled by laser ablation to form holes 2360 for vias. Otherwise, lithography could be used to form the via holes by patterning resists, exposing or developing the PID, depositing metal seed and plating such as with copper, and etching.

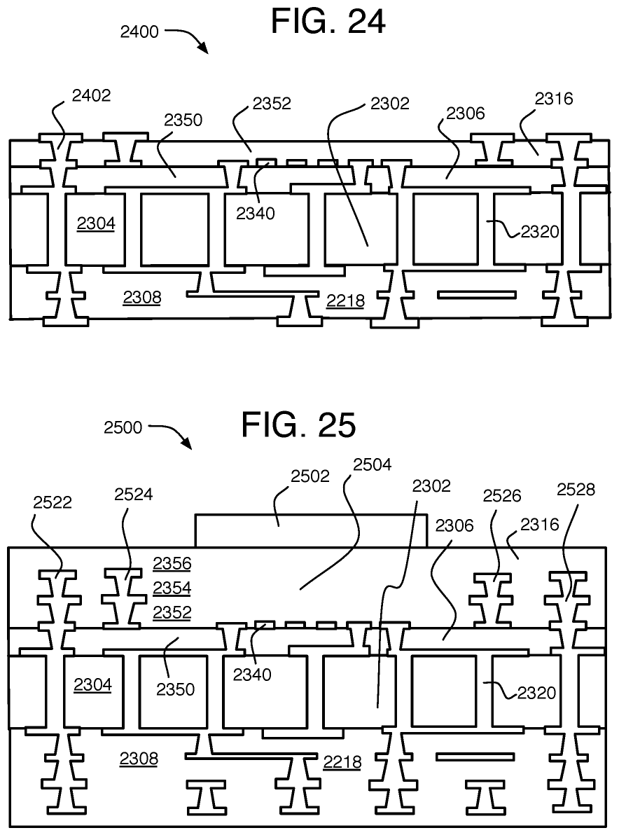

Referring to FIG. 24, in a stage 2400, the next level of vias may be formed by using a semi-adaptive process (SAP), where a seed layer is plated on the photo-imageable dielectric material layer 2352, the via holes 2402 are filled, and areas outside of the via holes are dry or wet etched.

Referring to FIG. 25, in a stage 2500, the process of laminating dielectric material layers and depositing or plating metallization is repeated until an upper-most dielectric material layer 2356 is deposited. A photoresist 2502, here being a positive photo resistive of with positive type PID materials, may include diazoalkylquinone, diazobenzoquinone, diazonaphtoquinone with an ester backbone, which generates a photo-acid that cleaves the ester. PR is different than PID in the sense that PR is removed (PID stays or is permanent). While a negative type PR is cured with light, a positive type PR becomes soluble with light. Resist and PID materials can either be laminated in dry film format or slit coated or spin coated for liquid formats. The photoresist may be patterned by a mask to cover only the area of the cavity to be removed.

If a curing inhibitor is being used, the curing inhibitor should be removed at this point, and whether that occurs before or after the photoresist is deposited depends on the type of curing inhibitor.

A cavity area 2504 is kept clear of metallization to provide sufficient space for the deep cavity. The width and length of the area may be at least 500 microns in both directions. The depth may be 50 to 200 microns by one example, and by another example more than 200 microns, such as 250 microns, at least depending on the size of the die to be placed in the cavity.

Stage 2500 also shows that incomplete core interconnects 2522, 2524, 2526, and 2528 are extending higher and are ready for a last via to extend through the upper-most built-up layer 2356 to couple to dice, other devices, or other metallization.

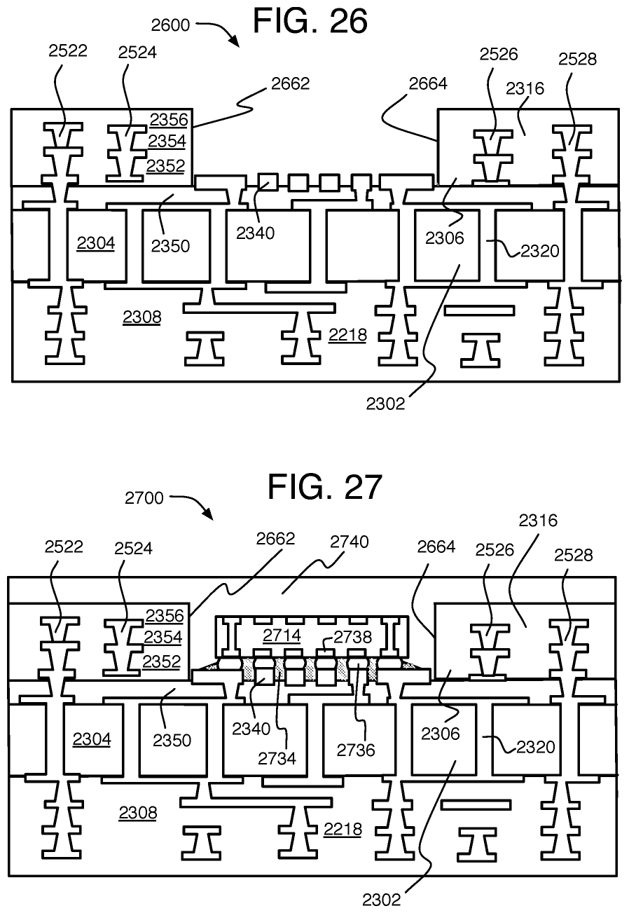

Referring to FIG. 26, in a stage 2600, the cavity area is exposed or developed, removing the photo-imageable material of the dielectric 2316 under the positive resist 2502 leaving a cavity 2662 with a vertical or substantially vertical sidewall 2664. By one form, this may be performed in a single exposure or shot to remove the entire desired depth of the cavity 2662. By one form, the cavity is rectangular in top view and the dimensions are as mentioned for the cavity area 2504.

Referring to FIG. 27, in a stage 2700, a die 2714 is attached to the metallization pattern 2340, and has die metallization including caps, pad, or contacts 2738 for engaging solder 2736 and forming lower bridge interconnects with coupled caps, pads, or contacts of the metallization pattern 2340. An underfill 2734 placed by capillary action is placed between the die 2714 and the metallization pattern 2340 and the lower dielectric material layer 2350.

The cavity 2662 is then filled, or at least the die 2714 is covered by an encapsulation material, here being a solder resist layer 2740 to protect the die and photo-imageable dielectric 2316. The materials of the solder resist 2740 are already mentioned above for solder resist layer 2284 with package 2200. The solder resist may be a dry film that is laminated onto the die and photo-imageable dielectric 2316.

The operations thereafter are performed to complete the package to a state as shown on package 2200 including the attachment of dice 2210 and 2212, and placement of underfill 2282 between the dice 2210 and 2212 and the solder resist layer 2740.

By yet another alternative, an iterative litho via (LiV) process also can be incorporated to create the deep cavity. Litho via is a technology where a resist is used to define a via pattern, and the via is then metallized by using SAP and plating techniques to metallize the via. The resist is then removed, the seed is etched, and the dielectric is deposited with some over burden. The via is revealed using a planarization process.

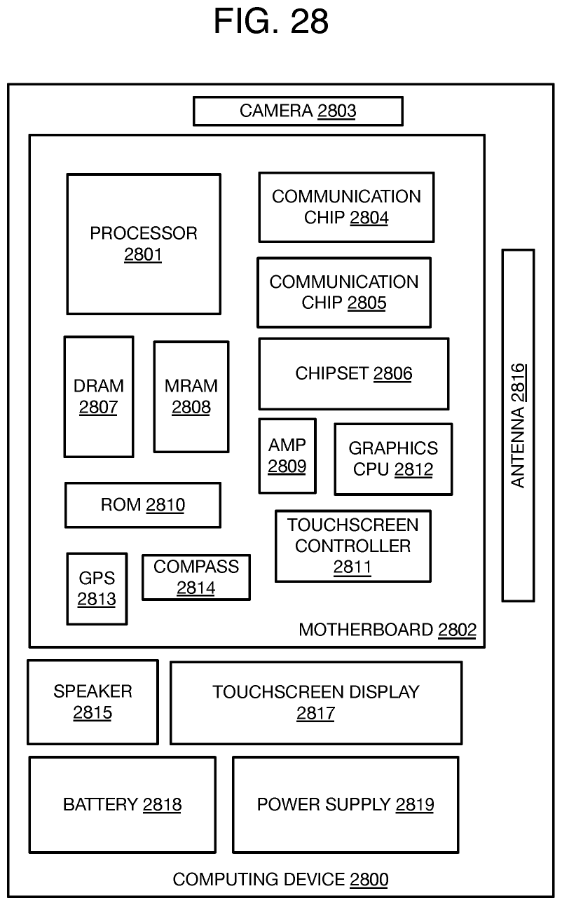

Referring to FIG. 28, an electronic computing device 2800 in accordance with at least one implementation herein of the disclosed devices may have a package substrate or mother board 2802 with a number of components, including but not limited to a processor (e.g., an applications processor) 2801. The processor 2801 may be physically and/or electrically coupled to the package substrate or board 2802. In some implementations, processor 2801 is within a composite IC chip structure, and the processor 2801 may include first circuitry with a package substrate and an embedded die, such as a bridge die, EMIB, EMIB-T, chiplet, or other die as described herein, for example. Processor 2801 may be implemented with circuitry in either or both of the host IC chips and chiplet. In general, the term “processor” or “microprocessor” may refer to any device or portion of a device that processes electronic data from registers and/or memory to transform that electronic data into other electronic data that may be further stored in registers and/or memory.

In various examples, one or more communication chips 2804 and 2805 also may be physically and/or electrically coupled to the package substrate or board 2802. In further implementations, communication chips 2804 and 2805 may be part of processor 2801. Depending on its applications, computing device 2800 may include other components that may or may not be physically and electrically coupled to package substrate or board 2802. These other components include, but are not limited to, volatile memory (e.g., DRAM 2807), non-volatile memory (e.g., ROM 2810), flash memory (e.g., NAND or NOR), magnetic memory (MRAM 2808), a graphics processor (CPU) 2812, a digital signal processor, a crypto processor, a chipset 2806, an antenna 2816, touchscreen display 2817, touchscreen controller 2811, battery unit 2818, audio codec, video codec, power amplifier 2809, global positioning system (GPS) device 2813, compass 2814, accelerometer, gyroscope, speaker 2815, camera 2803, and mass storage device (such as hard disk drive, solid-state drive (SSD), compact disk (CD), digital versatile disk (DVD), and so forth), and a power supply unit 2819, or the like. In some exemplary implementations, any of the IC structures, architecture, or units on device 2800 or described in any of the units mentioned above, may have the interconnect structure described above. Thus, for example, in addition to being formed by circuitry of processor 2801, or a composite IC chip of processor 2801, the first circuitry or first dice bridged by a second die or chiplet as described herein, also or instead may be implemented by an electronic memory (e.g., MRAM 2808 or DRAM 2807).

The communication chips 2804 and 2805 may enable wireless communications for the transfer of data to and from the computing device 2800. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some implementations the devices might not. The communication chip 2804 may implement any of a number of short-range wireless standards or protocols, including but not limited to Wi-Fi (IEEE 2802.11 family), Bluetooth, and others, and communications chip 2805 may implement longer-range wireless standards or protocols such as WiMAX (IEEE 2802.16 family), IEEE 2802.20, long term evolution (LTE), Ev-DO, HSPA+, HSDPA+, HSUPA+, EDGE, GSM, GPRS, CDMA, TDMA, DECT, derivatives thereof, as well as any other wireless protocols that are designated as 3G, 4G, 5G, and beyond.

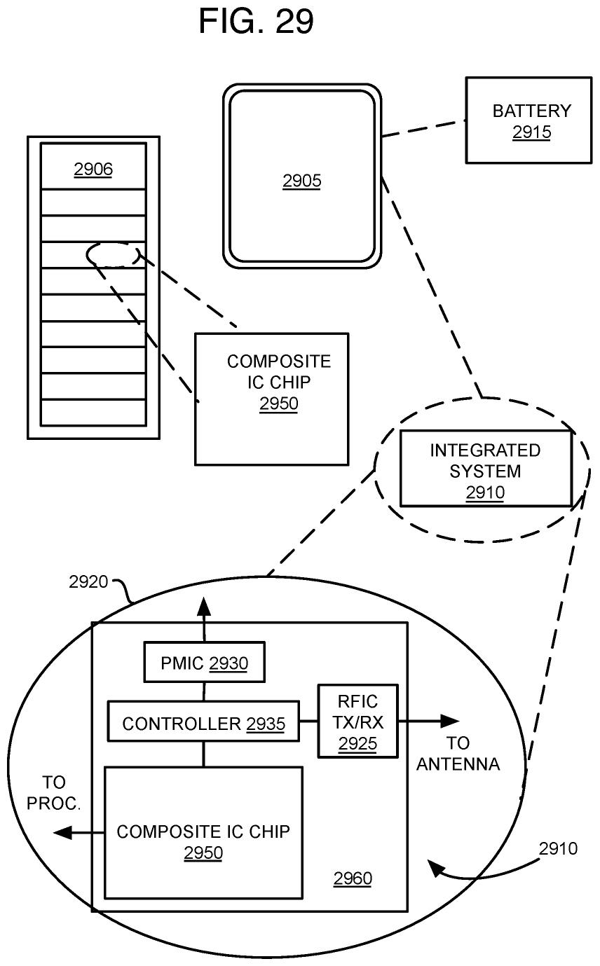

Referring to FIG. 29, a mobile computing platform 2905 and a data server machine 2906 employing an IC device included on a package substrate 2960 as described elsewhere herein. Computing device 100, 1100, and/or 2200 may be found inside platform 2905 or server machine 2906, for example. The server machine 2906 may be any commercial server, for example including any number of high-performance computing platforms disposed within a rack and networked together for electronic data processing, which in the exemplary implementation includes structure of at least one IC package on substrate 2960 and used to embed a bridge die, for example as described elsewhere herein, and may include a chiplet bonded to multiple die over a host IC chip and/or the package substrate 2960. The mobile computing platform 2905 may be any portable device configured for each of electronic data display, electronic data processing, wireless electronic data transmission, or the like. For example, the mobile computing platform 2905 may be any of a tablet, a smart phone, laptop computer, etc., and may include a display screen (e.g., a capacitive, inductive, resistive, or optical touchscreen), a chip-level or package-level integrated system 2910, and a battery 2915.

Whether disposed within the integrated system 2910 illustrated in the expanded view 2920, or as a stand-alone package within the server machine 2906, composite IC chip 2950 may include a package substrate with an embedded die, which may be a bridge die or chiplet bonded to multiple dice, for example as described elsewhere herein. Composite IC chip 2950 may be further coupled to or over package substrate 2960 and may comprise one or more of a power management integrated circuit (PMIC) 2930, RF (wireless) integrated circuit (RFIC) 2925 including a wideband RF (wireless) transmitter and/or receiver (TX/RX) (e.g., including a digital baseband and an analog front end module further comprises a power amplifier on a transmit path and a low noise amplifier on a receive path), and a controller 2935. PMIC 2930 may perform battery power regulation, DC-to-DC conversion, etc., and so has an input coupled to battery 2915 and with an output providing a current supply to other functional modules. As further illustrated, in the exemplary implementation, RFIC 2925 may have an output coupled to an antenna (not shown) to implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDcPA+, HSUPA+, EDGE, GSM, GPRS, CDMA, TDMA, DECT, Bluetooth, derivatives thereof, as well as any other wireless protocols that are designated as 3G, 4G, 4G, and beyond. Any of these IC units or components over the substrate may include the package substrate with an embedded die that may be a bridge die, chiplet, and/or EMIB with one or more interconnects to other die as described herein.

It is understood that the subject matter of the present description is not necessarily limited to specific applications illustrated in FIGS. 1-29. The subject matter may be applied to other electronic, microelectronic, or integrated circuit (IC) devices and assembly applications, as well as any appropriate electronic application, as will be understood to those skilled in the art.

The following examples pertain to further implementations. Specifics in the examples may be used anywhere in one or more implementations.

In an example 1, an electronic package comprises a substrate core; dielectric material of one or more dielectric material layers over the substrate core, and having a plurality of metallization layers comprising an upper-most metallization layer; an integrated circuit (IC) die embedded within the dielectric material and below the upper-most metallization layer; a metallization pattern within the dielectric material and below the IC die; and a gap within the dielectric material and extending around the metallization pattern.

In an example 2, the subject matter of example 1, wherein the package comprises a plurality of the gaps extending generally parallel to each other and being spaced one gap over another gap in a vertical array of the gaps within the dielectric material.

In an example 3, the subject matter of example 2, wherein at least one of the gaps is within a horizontal plane that intersects the IC die.

In an example 4, the subject matter of example 2 or 3, herein the gaps have an elongated direction extending around the IC die in top view, and wherein the vertical array comprises a bottom-most gap with a cross section transverse to the elongated direction and that has a height that is greater than the height of all other cross-sections of all other gaps in the vertical array.

In an example 5, the subject matter of any one of examples 1 to 4, wherein the gap has an elongated direction extending around the metallization pattern and a cross-section transverse to the elongated direction and having a height of 5 to 50 microns.

In an example 6, the subject matter of any one of examples 1 to 5, wherein the gap has an elongated direction extending around the metallization pattern and a cross-section transverse to the elongated direction and having a height of 35-45 microns.

In an example 7, the subject matter of any one of examples 1 to 6, wherein the gap is polygonal, quadrilateral, or rectangular around the metallization pattern and IC die in top view.

In an example 8, the subject matter of any one of examples 1 to 7, wherein the gap holds one or more gases.

In an example 9, the subject matter of any one of examples 1 to 8, wherein the IC die is at least one of: a bridge die, an embedded multi-die interconnect bridge (EMIB), an EMIB through silicon via (EMIB-T), or a chiplet.

In an example 10, a method of manufacturing an electronic package, comprises receiving an IC package substrate core with a first dielectric material layer of a first material over the package substrate and having a metallization pattern on the first dielectric material layer; placing a polymer layer with a material different than the first material over the metallization pattern; stacking one or more second dielectric material layers of the first material over the polymer layer, one or more of the second dielectric material layers having metallization outside of an outer periphery of the metallization pattern; drilling a cavity using a laser and through the stack of second dielectric material layers and to at least a depth of a top surface of the polymer layer; removing the polymer layer; and placing a die over the metallization pattern and within the cavity, and coupling the die to the metallization pattern.

In an example 11, the subject matter of example 10, comprises placing the polymer layer over a solder cap on the metallization pattern.

In an example 12, the subject matter of example 10 or 11, wherein the polymer layer has a material that is at least one of: Polynorborene, Polyalkylcarbonate, and Polyaldehyde.

In an example 13, the subject matter of any one of examples 10 to 12, wherein the polymer layer has a thickness of 5 to 50 microns.

In an example 14, the subject matter of any one of examples 10 to 13, wherein the polymer layer has a thickness over the metallization pattern that is equal to or greater than a tolerance depth of a laser arranged to drill the cavity.

In an example 15, the subject matter of any one of examples 10 to 14, comprising drilling the cavity to have an opening at an upper-most second dielectric material layer with a width of at least 500 microns.

In an example 16, an electronic system, comprises a substrate core; a dielectric material of two or more dielectric material layers stacked over the substrate core and having an upper-most dielectric material layer and a lower dielectric material layer having a lower metallization layer embedded within or on the lower dielectric material layer; a first integrated circuit (IC) die embedded within the dielectric material and over the lower dielectric material layer; a conductive feature between the first IC die and the lower metallization layer coupling the lower metallization to the first IC die; a second IC die positioned over the upper-most dielectric material layer and having a first interconnect to the first IC die and a second interconnect extending into the upper-most dielectric material layer outside of an outer periphery of the first IC die; and a horizontal distance from the conductive feature to the second interconnect that is at most 15 microns.

In an example 17, the subject matter of example 16, wherein the horizontal distance is at most 6 microns.

In an example 18, the subject matter of example 16 or 17, wherein the dielectric material layers comprise a photo-imageable material and a cavity with a vertical sidewall extending through the upper-most dielectric material layer to the lower dielectric material layer, and wherein the first die is disposed within the cavity.

In an example 19, the subject matter of example 16 or 17, comprising at least one elongated gap within at least one of the dielectric material layers below an upper-most metallization layer of the dielectric material layers and extending around the first IC die in top view.

In an example 20, the subject matter of any one of examples 19, comprising a plurality of the dielectric material layers collectively having a plurality of the elongated gaps arranged so that one elongated gap is spaced above another elongated gap in a vertical array of the elongated gaps.

While certain features set forth herein have been described with reference to various implementations, this description is not intended to be construed in a limiting sense. Hence, various modifications of the implementations described herein, as well as other implementations, which are apparent to persons skilled in the art to which the present disclosure pertains are deemed to lie within the spirit and scope of the present disclosure.

What is claimed is:

1. An electronic package, comprising:
a substrate core;
dielectric material of one or more dielectric material layers over the substrate core, and having a plurality of metallization layers comprising an upper-most metallization layer;
an integrated circuit (IC) die embedded within the dielectric material and below the upper-most metallization layer;
a metallization pattern within the dielectric material and below the IC die; and
a gap within the dielectric material and extending around the metallization pattern.

2. The electronic package of claim 1, comprising a plurality of the gaps extending generally parallel to each other and being spaced one gap over another gap in a vertical array of the gaps within the dielectric material.

3. The electronic package of claim 2, wherein at least one of the gaps is within a horizontal plane that intersects the IC die.

4. The electronic package of claim 2, wherein the gaps have an elongated direction extending around the IC die in top view, and wherein the vertical array comprises a bottom-most gap with a cross section transverse to the elongated direction and that has a height that is greater than the height of all other cross-sections of all other gaps in the vertical array.

5. The electronic package of claim 1, wherein the gap has an elongated direction extending around the metallization pattern and a cross-section transverse to the elongated direction and having a height of 5 to 50 microns.

6. The electronic package of claim 1, wherein the gap has an elongated direction extending around the metallization pattern and a cross-section transverse to the elongated direction and having a height of 35-45 microns.

7. The electronic package of claim 1, wherein the gap is polygonal, quadrilateral, or rectangular around the metallization pattern and IC die in top view.

8. The electronic package of claim 1, wherein the gap holds one or more gases.

9. The electronic package of claim 1, wherein the IC die is at least one of: a bridge die, an embedded multi-die interconnect bridge (EMIB), an EMIB through silicon via (EMIB-T), or a chiplet.

10. A method of manufacturing an electronic package, comprising:
receiving an IC package substrate core with a first dielectric material layer of a first material over the package substrate core and having a metallization pattern on the first dielectric material layer;
placing a polymer layer with a material different than the first material over the metallization pattern;
stacking one or more second dielectric material layers of the first material over the polymer layer, one or more of the second dielectric material layers having metallization outside of an outer periphery of the metallization pattern;
drilling a cavity using a laser and through the stack of second dielectric material layers and to at least a depth of a top surface of the polymer layer;
removing the polymer layer; and
placing a die over the metallization pattern and within the cavity, and coupling the die to the metallization pattern.

11. The method of claim 10, comprising placing the polymer layer over a solder cap on the metallization pattern.

12. The method of claim 10, wherein the polymer layer has a material that is at least one of: Polynorborene, Polyalkylcarbonate, and Polyaldehyde.

13. The method of claim 10, wherein the polymer layer has a thickness of 5 to 50 microns.

14. The method of claim 10, wherein the polymer layer has a thickness over the metallization pattern that is equal to or greater than a tolerance depth of a laser arranged to drill the cavity.

15. The method of claim 10, comprising drilling the cavity to have an opening at an upper-most second dielectric material layer with a width of at least 500 microns.

16. An electronic system, comprising:
a substrate core;
a dielectric material of two or more dielectric material layers stacked over the substrate core and having an upper-most dielectric material layer and a lower dielectric material layer having a lower metallization layer embedded within or on the lower dielectric material layer;
a first integrated circuit (IC) die embedded within the dielectric material and over the lower dielectric material layer;
a conductive feature between the first IC die and the lower metallization layer coupling the lower metallization to the first IC die;
a second IC die positioned over the upper-most dielectric material layer and having a first interconnect to the first IC die and a second interconnect extending into the upper-most dielectric material layer outside of an outer periphery of the first IC die; and
a horizontal distance from the conductive feature to the second interconnect that is at most 15 microns.

17. The system of claim 16, wherein the horizontal distance is at most 6 microns.

18. The system of claim 16, wherein the dielectric material layers comprise a photo-imageable material and a cavity with a vertical sidewall extending through the upper-most dielectric material layer to the lower dielectric material layer, and wherein the first die is disposed within the cavity.

19. The system of claim 17, comprising at least one elongated gap within at least one of the dielectric material layers below an upper-most metallization layer of the dielectric material layers and extending around the first IC die in top view.

20. The system of claim 19, comprising a plurality of the dielectric material layers collectively having a plurality of the elongated gaps arranged so that one elongated gap is spaced above another elongated gap in a vertical array of the elongated gaps.
